(19) United States
(12) Patent Application Publication
(10) Pub. No.: US 2023/0207606 A1
(43) Pub. Date: Jun. 29, 2023

(54) LIGHT EMITTING DIODE WITH ANGLE-DEPENDENT OPTICAL FILTER

(71) Applicant: Meta Platforms Technologies, LLC, Menlo Park, CA (US)

(72) Inventors: Samir MEZOUARI, Swindon (GB); Andrea PINOS, Plymouth (GB); Wei Sin TAN, Plymouth (GB)

(21) Appl. No.: 17/564,212

(22) Filed: Dec. 29, 2021

(51) Int. Cl. H01L 27/15; H01L 33/32; H01L 33/42; H01L 33/10

(52) U.S. Cl. CPC H01L 27/156; H01L 33/32; H01L 33/42; H01L 33/10

(57) ABSTRACT

Disclosed herein are techniques for extracting and collimating light emitted by a light emitting diode (LED). According to certain embodiments, a device includes an LED configured to emit light in a first wavelength range, and an angle-dependent optical filter optically coupled to the LED. A transmission (or reflection) wavelength range of the angle-dependent optical filter varies with an angle of incidence (AOI) of the light incident on the angle-dependent optical filter, such that the angle-dependent optical filter transmits most of light emitted from the LED and having small AOIs, and reflects most of light emitted from the LED and having large AOIs, thereby reducing the divergence angle of the emitted light.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AlN, GaN, InN, AlGaInP, other ternary and quaternary nitride, phosphide, and arsenide compositions, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro light emitting diode (micro-LED) devices. More specifically, this disclosure relates to micro-LED devices including angle-dependent optical filters for collimating emitted light (e.g., reducing emission angles) and enhancing luminance.

According to certain embodiments, a light emission structure may include a light emitting diode (LED) configured to emit light in a first wavelength range and an angle-dependent optical filter (or reflector, such as a notch filter) optically coupled to the LED. The angle-dependent optical filter may include a top layer, a bottom layer, and a stack of optical film layers between the top layer and the bottom layer. The stack of optical film layers between the top layer and the bottom layer may include first optical film layers including a first material having a first refractive index, and second optical film layers including a second material having a second refractive index. The second optical film layers may interleave with the first optical film layers. A shortest optical path length in each optical film layer of the first optical film layers and the second optical film layers may be ¼ of a second wavelength that is outside of the first wavelength range, and the shortest optical path length in each of the bottom layer and the top layer may be different from ¼ of the second wavelength. In some embodiments, the second wavelength may be longer than wavelengths in the first wavelength range.

In some embodiments of the light emission structure, the angle-dependent optical filter may be characterized by a transmission wavelength range that varies with an angle of incidence (AOI) of light incident on the angle-dependent optical filter. For a first AOI range, the transmission wavelength range may at least partially overlap with the first wavelength range of the light emitted from the LED, such that the angle-dependent optical filter is configured to mostly transmit light emitted from the LED and with AOIs in the first AOI range. For a second AOI range, the transmission wavelength range may not include or may only include a fraction of the first wavelength range of the light emitted from the LED, such that the angle-dependent optical filter is configured to mostly reflect light from the LED and with AOIs within the second AOI range. In some embodiments, the first AOI range may include AOIs equal to or less than 18.5°, and the second AOI range may include AOIs greater than 40°.

In some embodiments, the shortest optical path length of each of the bottom layer and the top layer may be shorter than a quarter of the second wavelength. For example, the shortest optical path length of each of the bottom layer and the top layer may be ⅛ of the second wavelength. In some embodiments, the shortest optical path length of each of the bottom layer and the top layer may be longer than a quarter of the second wavelength. For example, the shortest optical path length of each of the bottom layer and the top layer may be about 1.35 times of the quarter of the second wavelength.

In some embodiments, the light emission structure may include a reflective surface between the LED and the angle-dependent optical filter, where the reflective surface may be configured to scatter a first portion of light reflected by the angle-dependent optical filter back toward the angle-dependent optical filter. The reflective surface may include an opening configured to allow at least a portion of the light emitted by the LED to pass through, and allow a second portion of the light reflected by the angle-dependent optical filter to the opening to pass through and enter the LED.

In some embodiments, the first material may include gallium nitride (GaN) with a porosity less than 10%, and the second material may include porous GaN with a porosity equal to or greater than 10%. In some embodiments, the light emission structure may include a transparent electrode for the LED, where the angle-dependent optical filter may be between the LED and the transparent electrode. In some embodiments, each of the first material and the second material may include a respective transparent dielectric material, and the respective transparent dielectric material may include SiO₂, TiO₂, Ta₂O₅, Al₂O₃, HfO₂, or another metal oxide that is transparent to visible light. In some embodiments, each of the bottom layer and the top layer may include the first material, the second material, or a third material different from the first material and the second material and having a third refractive index. In some embodiments, the angle-dependent optical filter may include a notch filter, where, for incident light with an AOI of 0°, a central wavelength of the notch filter may be equal to the second wavelength.

According to some embodiments, an LED device may include an array of LEDs configured to emit light in a first wavelength range, and an angle-dependent optical reflector (or filer, such as a notch filter) optically coupled to the array of LEDs. A reflection wavelength range of the angle-dependent optical reflector may vary with an angle of incidence (AOI) of the light incident on the angle-dependent optical reflector. For incident light with AOIs within a first AOI range (e.g., lower than a first threshold value), the reflection wavelength range of the angle-dependent optical reflector may not include most or all of the first wavelength range such that a majority of the light that is emitted by the array of LEDs and is incident on the angle-dependent optical reflector at AOIs within the first AOI range may be transmitted by the angle-dependent optical reflector. For incident light with AOIs within a second AOI range (e.g., greater than a second threshold value), the reflection wavelength range of the angle-dependent optical reflector may include most or all of the first wavelength range such that a majority of the light that is emitted by the array of LEDs and is incident on the angle-dependent optical reflector at AOIs within the second AOI range may be reflected by the angle-dependent optical reflector back toward the array of LEDs.

In some embodiments, the angle-dependent optical reflector may include a top layer, a bottom layer, and a layer stack between the top layer and the bottom layer. The layer stack includes first optical film layers interleaved with second optical film layers. A shortest optical path length in each optical film layer of the first optical film layers and the second optical film layers may be a quarter of a second wavelength that is outside of the first wavelength range. A shortest optical path length in each of the bottom layer and the top layer may be different from the quarter of the second wavelength. In some embodiments, the first optical film layers may include gallium nitride (GaN) with a porosity less than 10%, and the second optical film layers include porous GaN with a porosity equal to or greater than 10%. In some embodiments, the LED device may also include a reflective surface between the array of LEDs and the angle-dependent optical reflector, where the reflective surface may be configured to scatter a first portion of the light that is reflected by the angle-dependent optical reflector back toward the angle-dependent optical reflector.

According to certain embodiments, a method for collimating light emitted by an LED may include receiving, by an angle-dependent optical reflector, light emitted by the LED and within a first wavelength range. A reflection wavelength range of the angle-dependent optical reflector may vary with the AOI of light incident on the angle-dependent optical reflector. The method may also include transmitting, by the angle-dependent optical reflector, a majority of light received from the LED and with AOIs less than a first threshold value, where, for light with AOIs less than the first threshold value, the reflection wavelength range of the angle-dependent optical reflector may not include most or all of the first wavelength range. The method may further include reflecting, by the angle-dependent optical reflector, a majority of light received from the LED and with AOIs greater than a second threshold value, where, for light with AOIs greater than the second threshold value, the reflection wavelength range of the angle-dependent optical reflector may include most or all of the first wavelength range.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIG. 8A illustrates an example of an LED device.

FIG. 8B illustrates a simulated beam intensity profile of a light beam emitted by the example of the LED device of FIG. 8A.

FIG. 8C illustrates the total optical energy and average intensity within different emission cones of a light beam emitted by the example of the LED device of FIG. 8A.

FIG. 9A illustrates an example of an optical notch filter that can be used as an angle-dependent optical filter/reflector for collimating light beams emitted by an LED according to certain embodiments.

FIG. 9B illustrates the reflectivity of the example of optical notch filter of FIG. 9A as a function of the wavelength of surface-normal incident light.

FIGS. 10A-10D illustrate the reflectivity of an example of an optical notch filter as a function of the wavelength of the incident light with different incident angles.

FIG. 11A illustrates an example of an LED device with an angle-dependent optical filter according to certain embodiments.

FIG. 11B illustrates a simulated beam intensity profile of a light beam emitted by the example of the LED device of FIG. 11A.

FIG. 11C illustrates the total optical energy and average intensity within different emission cones of a light beam emitted by the example of the LED device of FIG. 11A.

FIG. 12A illustrates the reflectivity of an example of an angle-dependent optical filter for blue light as a function of the wavelength of the incident light at different incident angles.

FIG. 12B illustrates the reflectivity of an example of an angle-dependent optical filter for green light as a function of the wavelength of the incident light at different incident angles.

FIG. 12C illustrates the reflectivity of an example of an angle-dependent optical filter for red light as a function of the wavelength of the incident light at different incident angles.

FIG. 13 illustrates an example of an LED device including an angle-dependent optical filter according to certain embodiments.

FIG. 14A illustrates a simulated beam intensity profile of a light beam emitted by the example of the LED device of FIG. 13.

FIG. 14B illustrates the total optical energy and average intensity within different emission cones of a light beam emitted by the example of the LED device of FIG. 13.

FIGS. 15A-15B illustrate cross-sectional views of examples of angle-dependent optical filters according to certain embodiments.

FIG. 16 illustrates a cross-sectional view of an examples of an LED device including an internal angle-dependent optical filter according to certain embodiments.

FIG. 17 is a flowchart illustrating an example of a method of collimating light emitted by LEDs using an angle-dependent optical filter according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to light emitting diodes (LEDs). More specifically, and without limitation, disclosed herein are techniques for reducing emission angles and enhancing luminance of LEDs (e.g., micro-LEDs) using angle-dependent optical thin-film filters (functioning as angle-dependent optical reflectors). Various inventive embodiments are described herein, including devices, systems, structures, methods, processes, materials, and the like.

Micro-LEDs can be used in conjunction with various technologies, such as image displaying in artificial reality systems. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some artificial reality systems, the artificial images may be presented to users using an LED-based display subsystem.

When used in these applications, LEDs, especially micro-LEDs, may be coupled to an imaging optical system to present artificial images to users. Some imaging optical systems may only use light within a small light emission cone (solid angle), such as light with beam angles within about ±20 degrees. However, many micro-LEDs may be close to Lambertian emitters, where the intensity of the light emitted at an emission angle θ with respect to the surface normal direction of the micro-LED may be proportional to the cosine of the emission angle θ (e.g., I(θ)=I₀ cos(θ)). Therefore, a large portion of the emitted light may be outside of the small light emission cone and thus may not be used by the imaging optical system and may become stray light. This may not only result in a low energy efficiency but may also reduce the resolution and contrast of the displayed images. Light extraction structures, such as micro-lenses, prisms, or gratings, may be used to collimate and/or redirect light beams emitted by the micro-LEDs. But it may be difficult and costly to make these light extraction structures on micro-LEDs.

According to certain embodiments disclosed herein, an LED device (e.g., including an array of LEDs, such as micro-LEDs) may include a flat collimator formed by an angle-dependent optical filter (reflector) in the light path of the light emitted from the LEDs. The angle-dependent optical filter may be a notch filter with a central wavelength different from the wavelength of the light emitted by the LEDs, and thus may have a low reflectance for incident light from the LEDs and at small incident angles, but may have much higher reflectance for light incident from the LEDs at large incident angles. Therefore, light emitted from the LEDs (e.g., within a certain wavelength range) and passing through the angle-dependent optical filter may have much higher intensities at small emission angles and very low intensities at larger emission angles. As such, the emission angle of the LEDs may be reduced and the emitted light may effectively be collimated by the angle-dependent optical filter. In some embodiments, the LED device may include a reflective layer with a rough reflective surface between the angle-dependent optical filter and the LEDs, such that at least a portion of the light reflected by the angle-dependent optical filter (e.g., light emitted by the LEDs at large emission angles and having large angles of incidence at the angle-dependent optical filter) may be scattered by the rough reflective surface to the angle-dependent optical filter at lower incident angles and thus may pass through the angle-dependent optical filter with low reflectance.

In some embodiments, the angle-dependent optical filter may be characterized by a transmission wavelength range that varies with the angle of incidence (AOI) of the light incident on the angle-dependent optical filter. For example, the wavelength range of the light emitted by the LED may be mostly or fully within the transmission wavelength range of the angle-dependent optical filter for small AOIs (e.g., within about ±20°), but may be mostly or completely outside of the transmission wavelength range of the angle-dependent optical filter for incident light with larger AOIs. For example, when light is incident on the angle-dependent optical filter at larger AOIs (e.g., greater than about 20°, 30°, or 40°), the wavelength range of the light emitted from the LED may be within the reflection wavelength range of the angle-dependent optical filter, such that the angle-dependent optical filter may mostly reflect the incident light with the large AOIs back to the LEDs. As such, the angle-dependent optical filter may mostly transmit incident light with small AOIs. As a result, a light beam emitted from the LED device may have a low divergence angle.

The angle-dependent optical filter disclosed herein may have a flat structure that includes multiple layers of optical thin films with alternating refractive indices arranged in a stack (referred to hereinafter as “optical film stack”). The angle-dependent optical filter may include dielectric materials (e.g., TiO₂, SiO₂, and/or other oxides) or semiconductor materials. The optical film stack may be formed by epitaxial layers grown on LED epitaxial layers, or may be pre-made on a transparent substrate and then placed on top of the light emitting surface of the LED (e.g., through a spacer). For example, in some embodiments, the angle-dependent optical filter may be made of thin layers of a semiconductor material (e.g., GaN) with different porosities and thus different refractive indices, and can be formed by epitaxially growing the thin layers of the semiconductor material with different doping densities and selectively porosifying, for example, the semiconductor layers with a higher doping density. The thin layers of the semiconductor material may be grown on the light emitting side of the micro-LED wafer before or after growing the epitaxial layers of the micro-LED wafer, or may be grown on another substrate (e.g., a sapphire substrate).

To achieve the angle-dependent reflectivity described above, the angle-dependent optical filters (e.g., notch filters) disclosed herein may have structures different from conventional distributed Bragg reflectors (DBRs). For example, the angle-dependent optical filters disclosed herein may have a top layer and a bottom layer that sandwich other layers of the optical film stack, where the optical thickness (referred to herein as the product of the physical thickness and the refractive index) of the top layer of the optical film stack and the optical thickness of the bottom layer of the optical film stack may be different from a uniform optical thickness of other layers of the optical film stack. Specifically, the optical thickness of each of the other layers of the optical film stack may be about a quarter of the wavelength of the central wavelength of the notch filter, where the central wavelength of the notch filter may be longer than the wavelength of the incident light such that the wavelength of the incident light may be outside of the reflection wavelength range of the notch filter for incident light with small AOIs. The top layer and the bottom layer of the optical film stack may both have an optical thickness different from the optical thickness of the other layers in the optical film stack, such as thicker or thinner than a quarter of the central wavelength of the notch filter. In one example, the top layer and the bottom layer of the optical film stack may both have an optical thickness about 0.5 or 1.35 times of a quarter of the central wavelength of the notch filter.

Therefore, compared with conventional methods such as using refractive optics (e.g., convex lenses) formed by etching (e.g., using a gray-scale mask) in the epitaxial layers or an oxide layer deposition on the epitaxial layers, or using parabolic reflectors formed on parabolic-shaped mesa structures etched in the epitaxial layers, techniques disclosed herein can achieve light collimation in a more cost-effective and a more efficient manner using flat optical components that are easy to manufacture. Moreover, the angle-dependent optical filter disclosed herein can have very low (e.g., close to 0%) reflectance for incident light with small incident angles and can have very high (e.g., close to 100%) reflectance for incident light with large incident angles, and thus can reduce the emission angle and improve the intensity of the emitted light within small emission cones. Light extraction efficiencies may be improved, for example, using the rough reflective surface. The overall efficiency and performance of a display system may be improved due to the improved light extraction efficiency, the smaller emission angle, and the reflection of light that may otherwise become stray light (e.g., light with large incident angles).

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs), each including multiple (e.g., about 2 to 6) quantum wells.

As used herein, the term “micro-LED” or “μLED” refers to an LED that has a chip where a linear dimension of the chip is less than about 200 μm, such as less than 100 μm, less than 50 μm, less than 20 μm, less than 10 μm, or smaller. For example, the linear dimension of a micro-LED may be as small as 6 μm, 5 μm, 4 μm, 2 μm, or smaller. Some micro-LEDs may have a linear dimension (e.g., length or diameter) comparable to the minority carrier diffusion length. However, the disclosure herein is not limited to micro-LEDs, and may also be applied to mini-LEDs and large LEDs.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

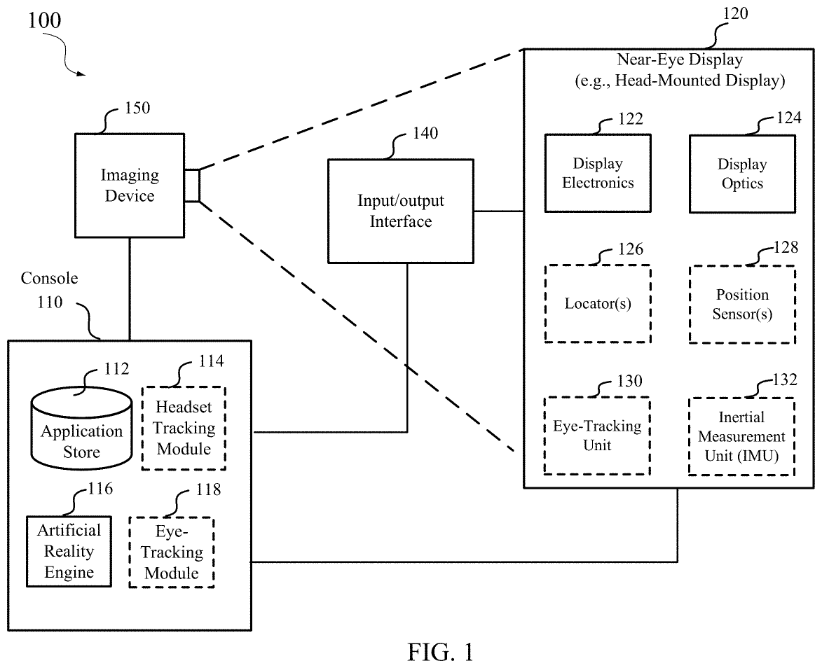

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

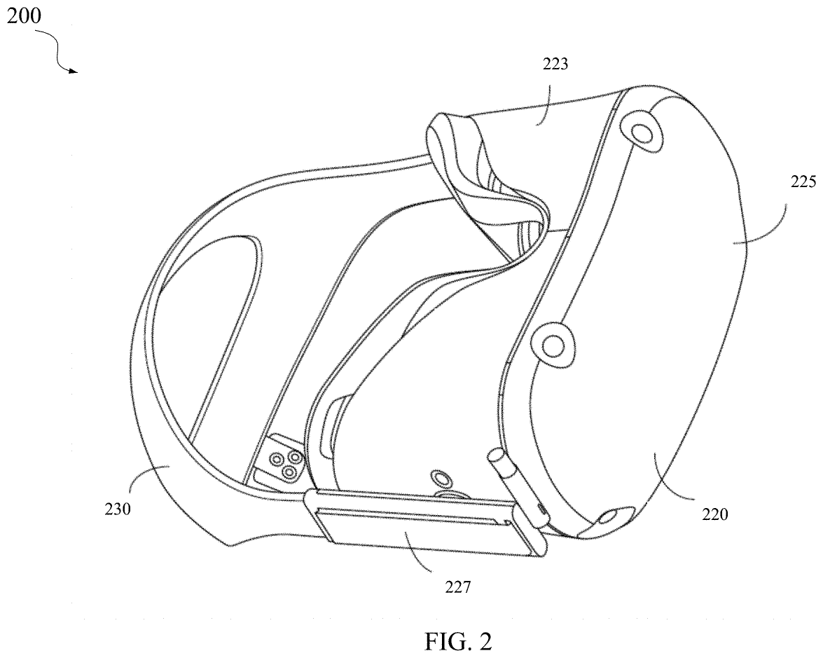

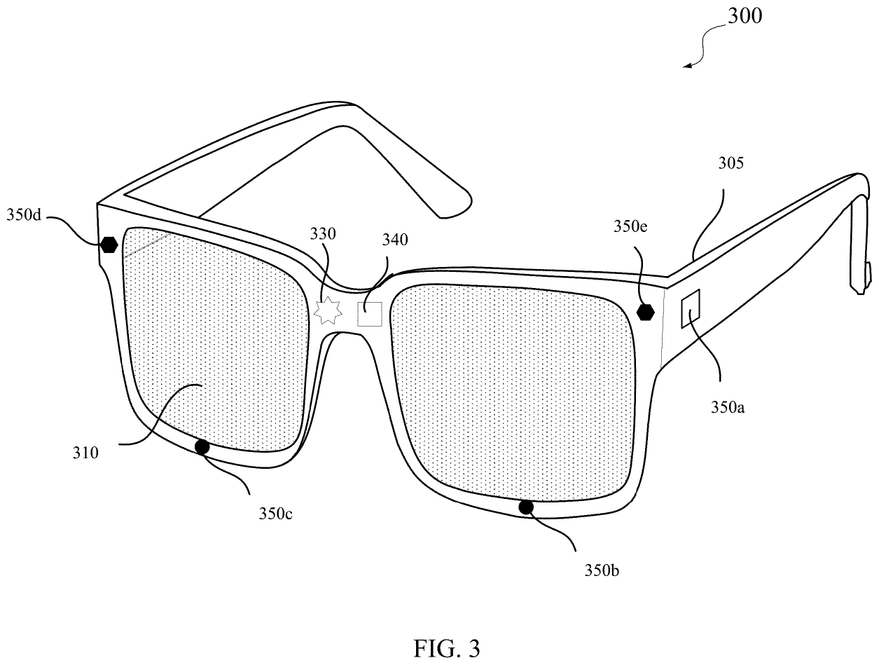

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to determine the eye's orientation more accurately.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

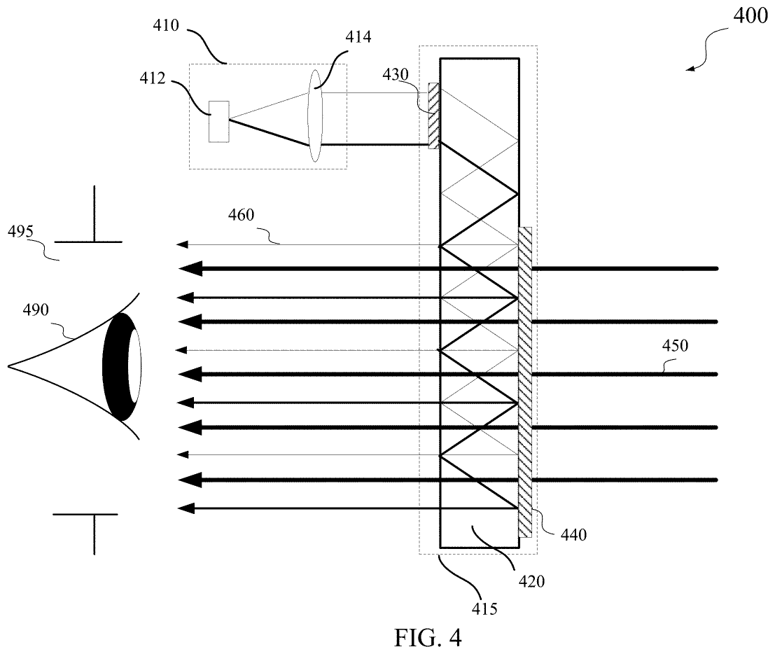

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

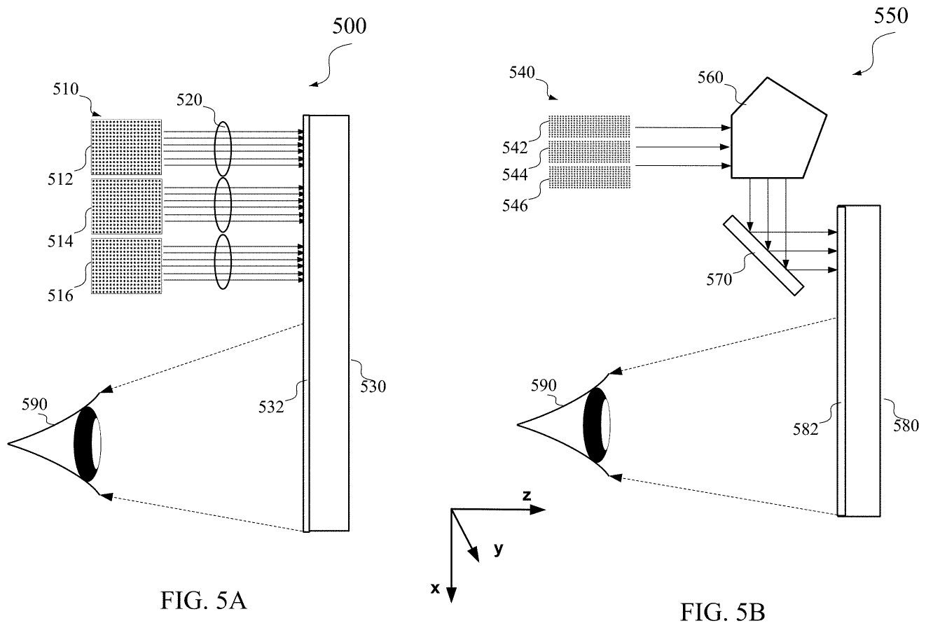

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

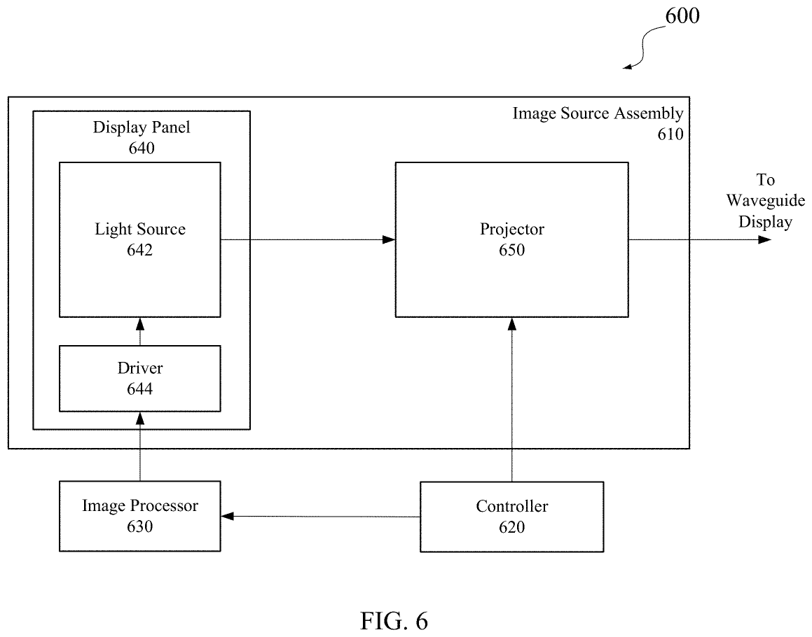

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging. In some embodiments, to increase the light extraction efficiency, a mesa that includes at least some of the layers of semiconductor materials may be formed.

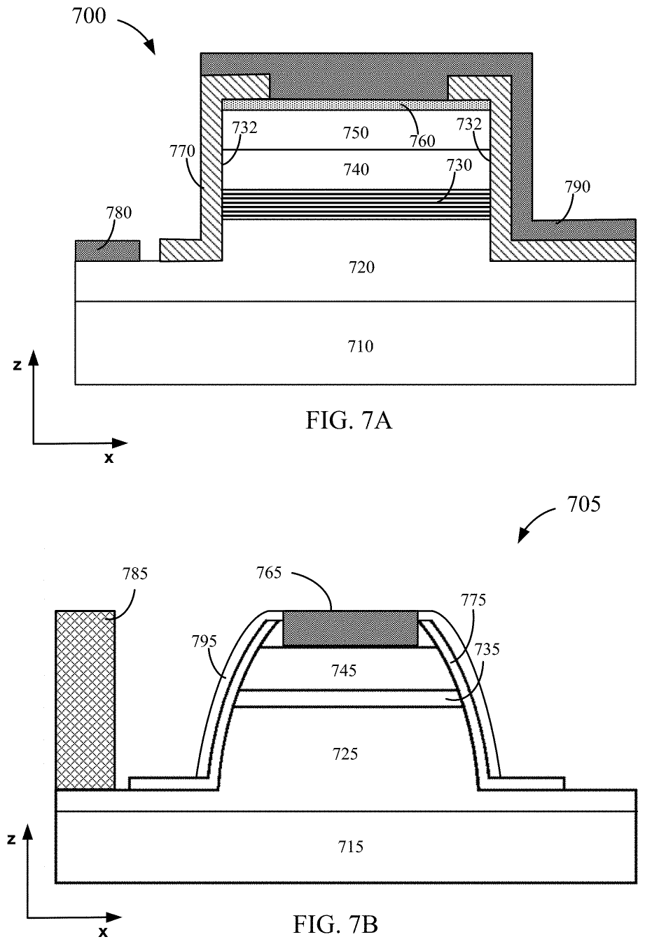

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on mesa sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiNx) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across electrical contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Driver circuits (e.g., driver circuit 644) may be fabricated, for example, on a silicon wafer using CMOS processes. The LEDs and the driver circuits on wafers may be diced and then bonded together, or may be bonded on the wafer level and then diced. Various bonding techniques can be used for bonding the LEDs and the driver circuits, such as adhesive bonding, metal-to-metal bonding, metal oxide bonding, wafer-to-wafer bonding, die-to-wafer bonding, hybrid bonding, and the like.

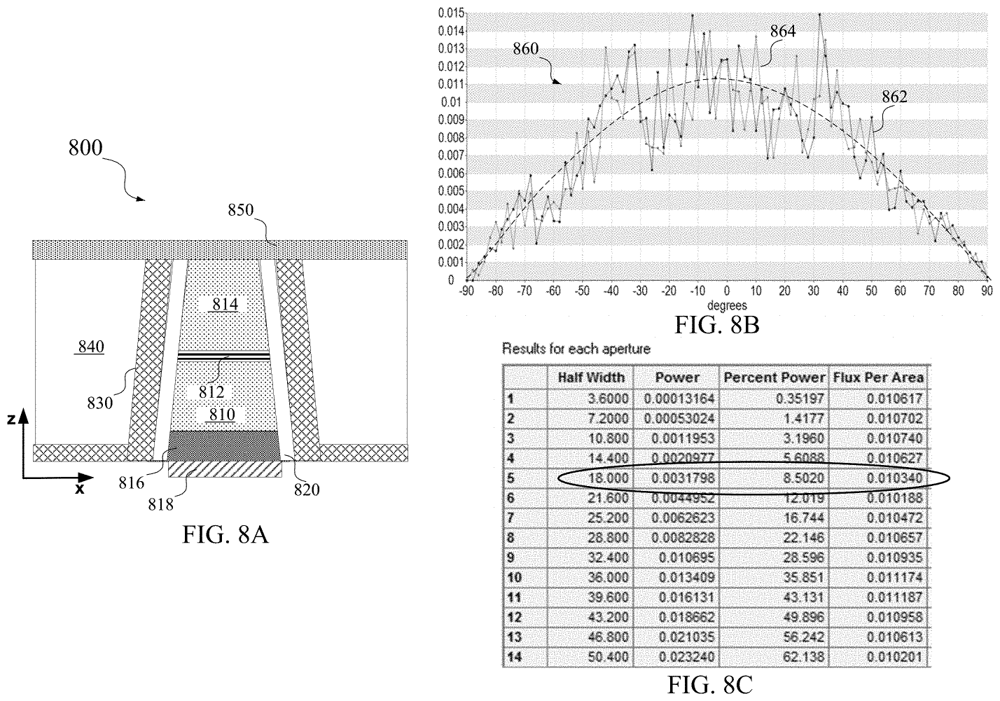

FIG. 8A illustrates an example of an LED device 800. LED device 800 may include an array of LEDs (e.g., micro-LEDs). Each LED may include a mesa structure that may have a conical shape and may include semiconductor epitaxial layers, such as a first semiconductor layer 810 (e.g., a p-doped GaN layer including dopants such as Mg, Ca, Zn, or Be), an active region 812 (e.g., including InGaN/GaN quantum wells), and a second semiconductor layer 814 (e.g., an n-doped GaN layer including dopants such as Si or Ge). Each LED may also include a back reflector 816 (e.g., including a reflective metal such as Ag, Al, or Au) and an electrical contact 818 (e.g., a p-contact or p electrode) at the bottom of the mesa structure. Each LED may further include a passivation layer 820 (e.g., a dielectric material such as SiO₂ or SiN) that electrically isolates the LED from other LEDs, and a sidewall reflector 830 (e.g., including a reflective metal such as Al) that optically isolates the LED from other LEDs. Regions 840 between the mesa structures may be filled with one or more conductive materials (e.g., including a barrier layer such as TiN or TaN, and a filler metal such as Al, Cu, W, Ti, or Au) and/or a dielectric material (e.g., SiO₂ or SiN). The one or more conductive materials and/or sidewall reflector 830 may be used to connect a transparent conductive layer 850 (e.g., an indium tin oxide (ITO) layer, which may be an electrode such as an n-contact) to drive circuits.

Active region 812 may emit photons when a current flows through an LED. The photons may be emitted in any directions. Photons that reach back reflector 816 and sidewall reflector 830 may be reflected. Some photons may exit the LED through transparent conductive layer 850, while some photons may be reflected back to the LED due to, for example, total internal reflection at the light emitting surface (e.g., the top surface of transparent conductive layer 850). Therefore, some photons may be trapped in the LED and may be absorbed by the semiconductor materials. As such, the light extraction efficiency may be low. In addition, light emitted from the light emitting surface may exit the LED in any emission angle θ between ±90° with respect to the surface-normal direction of the light emitting surface. Thus, the emission cone may be large.

FIG. 8B illustrates a simulated beam intensity profile 860 of a light beam emitted by LED device 800 of FIG. 8A. Curves 862 and 864 in FIG. 8B show the simulated beam intensity as a function of the emission angle in the x-z plane and the y-z plane, respectively. As illustrated, the light beam may include light in any emission angle θ between ±90° with respect to the surface-normal direction of the light emitting surface. The intensity of the light emitted at an emission angle θ with respect to the surface-normal direction of the light emitting surface may be approximately proportional to the cosine of the emission angle θ (e.g., 40)=I₀ cos(θ)). Therefore, the LED may be close to a Lambertian light emitter.

FIG. 8C illustrates the total optical energy and average intensity within different emission cones of a light beam emitted by LED device 800 of FIG. 8A. As shown in FIG. 8C, the total optical power for emitted light with emission angles within ±18° (which is the light that may be accepted by the display optics of a near-eye display system) is only about 0.0032 units or about 8.5% of the total power of the light emitted from the LED. Therefore, the overall efficiency of the display system may be very low. In order to improve the overall efficiency of the display system, the light extraction efficiency and the coupling efficiency of the emitted light to the display system may need to be improved.

In some embodiments, light extraction structures such as micro-lenses may be used to improve the light extraction efficiency and to collimate the light beams emitted by LEDs. Micro-lenses may be made by, for example, etching one or more semiconductor layers or one or more transparent dielectric material layers deposited on the LEDs using etching techniques that are capable of variable depth etching, such as gray-tone lithography techniques. In some embodiments, a reflective collimator may be made on each LED by, for example, forming a mesa structure with a parabolic shape and with the light emitting region at the focal point of the parabolic shape and then forming a reflector layer on the mesa structures. Such processes can be difficult and costly to implement. Diffractive optical elements such as Fresnel lenses may be used for collimating the emitted light, but the diffraction efficiency may be low.

According to certain embodiments, an angle-dependent optical filter (or reflector) may be used in an LED device (e.g., including an array of LEDs, such as micro-LEDs) to collimate the light beams emitted by the LEDs or otherwise improve the beam profiles of the light beams. The angle-dependent optical filter may have a reflection wavelength range that varies with the incident angle of the incident light. The angle-dependent optical filter may be implemented using a notch filter having a central wavelength different from the wavelengths of the light emitted by the LEDs, and thus may have a low reflectance for incident light from the LEDs and having small incident angles, but may have much higher reflectance for incident light from the LEDs and having large incident angles. Therefore, light emitted from the LEDs and passing through the angle-dependent optical filter may have higher intensities at small emission angles and lower intensities at large emission angles. As such, the emission angle of the LEDs may be reduced and the emitted light may effectively be collimated by the angle-dependent optical filter.

In some embodiments, the angle-dependent optical filter may be characterized by a transmission wavelength range that varies with the angle of incidence (AOI) of the light incident on the angle-dependent optical filter. For example, the wavelength range of the light emitted by the LED may be mostly or fully within the transmission wavelength range of the angle-dependent optical filter for small AOIs (e.g., within about ±20°, about ±30°, or about ±40°), but may be mostly or completely outside of the transmission wavelength range of the angle-dependent optical filter for incident light with large AOIs. For example, when light is incident on the angle-dependent optical filter at large AOIs (e.g., greater than about 20°, 30°, or 40°), the wavelength range of the light emitted from the LED may be mostly or completely within the reflection wavelength range of the angle-dependent optical filter, such that the angle-dependent optical filter may mostly reflect the incident light with the large AOIs back to the LEDs. As such, the angle-dependent optical filter may mostly transmit incident light with small AOIs. As a result, a light beam emitted from the LED device may have a low divergence angle.

The angle-dependent optical filter disclosed herein may have a flat structure that includes multiple layers of optical thin films with alternating refractive indices arranged in an optical film stack. The angle-dependent optical filter may include dielectric materials (e.g., TiO₂, SiO₂, and/or other oxides) or semiconductor materials. The optical film stack may be grown on the LED epitaxial layers or grown on another substrate (e.g., glass or sapphire) using the same techniques for growing the LED epitaxial layers, or may be formed on a transparent substrate and then placed on top of the LED light emitting surface (e.g., through a spacer). For example, in some embodiments, the angle-dependent optical filter may be made of thin layers of a semiconductor material (e.g., GaN) with different porosities and thus different refractive indices, and can be formed by epitaxially growing the thin layers of the semiconductor material with different doping densities and selectively porosifying, for example, the semiconductor layers with a higher doping density. The thin layers of the semiconductor material may be grown on the light emitting side of the micro-LED wafer before or after growing the epitaxial layers of the micro-LED wafer, or may be grown on another substrate (e.g., a sapphire substrate). In another example, the angle-dependent optical filter may be made by coating or depositing uniform layers of dielectric materials, such as SiO₂, TiO₂, Ta₂O₅, Al₂O₃, HfO₂, or other metal oxides that may be transparent to visible light on a transparent substrate, such as a glass or quartz substrate, using optical thin-film coating techniques such as various vapor deposition techniques (e.g., ion-assisted electron-beam evaporative deposition) or sputtering techniques (e.g., ion beam sputtering (IBS), advanced plasma sputtering (APS), or plasma assisted reactive magnetron sputtering (PARMS)). The transparent substrate with the dielectric layers formed thereon may then be attached to the LED device, for example, using a spacer.

In some embodiments, the LED device may include a reflective layer with a rough reflective surface between the angle-dependent optical filter and the LEDs, such that at least a portion of the light reflected by the angle-dependent optical filter (e.g., light emitted by the LEDs at large emission angles and having large angles of incidence at the angle-dependent optical filter) may be scattered by the rough reflective surface to the angle-dependent optical filter at lower incident angles and thus may pass through the angle-dependent optical filter with low reflectance.

Therefore, techniques disclosed herein can achieve light collimation in a more cost-effective and a more efficient manner using flat optical components that may be relatively easy to manufacture, compared with conventional methods such as using refractive optics (e.g., convex lenses) formed by etching (e.g., using a gray-scale mask) in the epitaxial layers or an oxide layer deposition on the epitaxial layers, or using parabolic reflectors formed on parabolic-shaped mesa structures etched in the epitaxial layers. Moreover, the angle-dependent optical filter disclosed herein can have very low (e.g., close to 0%) reflectance for incident light with small incident angles, and can have very high (e.g., close to 100%) reflectance for incident light with large incident angles, and thus can reduce the emission angle and improve the intensity of the emitted light within the emission cone. Light extraction efficiencies may be improved, for example, using the rough reflective surface. The overall efficiency and performance of a display system may be improved due to the improved light extraction efficiency, the smaller emission angle, and the reflection of light that may otherwise become stray light (e.g., light with large incident angles).

To achieve the angle-dependent reflectivity described above, the angle-dependent optical filters (e.g., notch filters) disclosed herein may need to have structures different from conventional distributed Bragg reflectors (DBRs). DBRs may be used in some light emitting devices, such as some LEDs (e.g., resonant cavity LEDs) and vertical-cavity surface-emitting lasers (VCSELs), to reflect light emitted in the active region and/or form a resonant cavity. In contrast, the angle-dependent optical filters disclosed herein are configured to transmit light emitted in the active region and having small emission angles, and reflect light emitted in the active region and having large emission angles.

A conventional DBR may include alternated layers of high-index and low-index materials, such as TiO₂ and SiO₂, where each layer may have an optical thickness (referred to as the product of the physical thickness and the refractive index) about, for example, a quarter of the target wavelength to be reflected. For surface-normal incident light of the target wavelength, the optical path length difference between the reflections at adjacent interfaces between the layers may be about a half of the target wavelength, and the reflection coefficients at the adjacent interfaces may have alternating signs due to the alternating refractive indices. Therefore, the light reflected from the interfaces may constructively interfere, thereby resulting in a high reflectance. The reflectivity of a DBR can be higher when the difference in refractive index between the high-index layer and the low-index layer (referred to herein as refractive index contrast or just index contrast) is higher and/or when the number of pairs of the high-index layer and the low-index layer is larger. A higher refractive index contrast may also correspond to a larger reflection wavelength range.

Compared with conventional DBRs, the angle-dependent optical filters disclosed herein may have a top layer and a bottom layer that sandwich other layers of the optical film stack, where the optical thickness of the top layer and the optical thickness of the bottom layer of the optical film stack may be different from a uniform optical thickness of other layers of the optical film stack. Specifically, the optical thickness of each of the other layers of the optical film stack may be about a quarter of the central wavelength of the notch filter, which may be longer than the wavelength of the incident light such that the wavelength of the incident light may be outside of the reflection wavelength range of the notch filter. The top layer and the bottom layer of the optical film stack may both have an optical thickness different from the optical thickness of the other layers in the optical film stack, such as thicker or thinner than a quarter of the wavelength of the central wavelength of the notch filter.

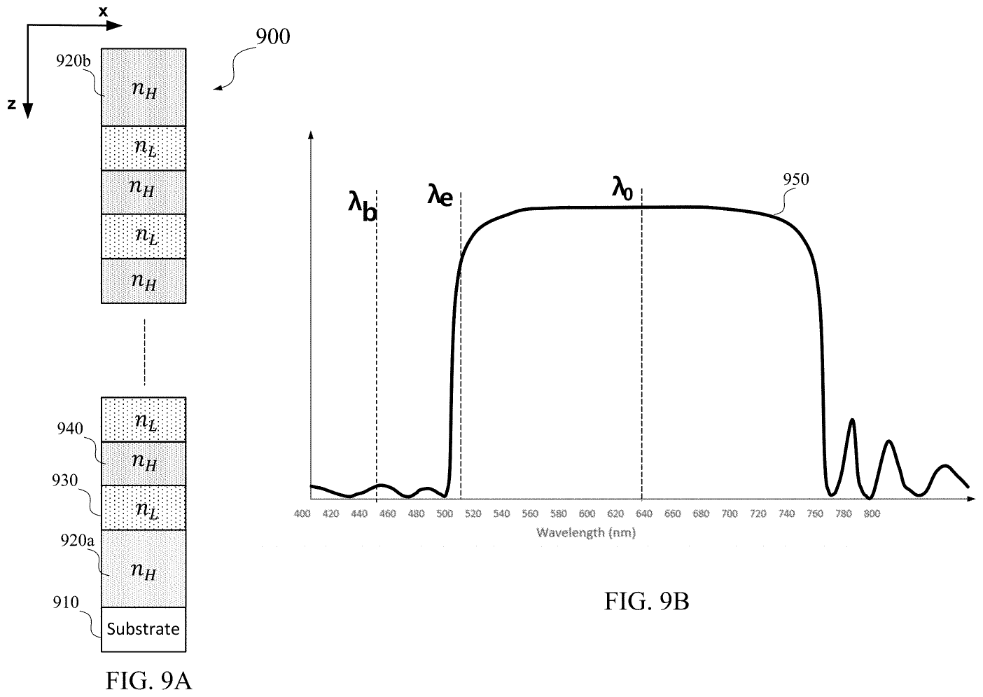

FIG. 9A illustrates an example of an optical notch filter 900 that may be used as the angle-dependent optical filter for collimating light beams emitted by an LED according to certain embodiments. In the illustrated example, optical notch filter 900 may include a substrate 910 (e.g., a glass or quartz substrate) and multiple optical thin-film layers formed on substrate 910. The multiple optical thin-film layers may include dielectric or semiconductor materials, and may include, for example, a bottom layer 920a, a top layer 920b, and a plurality of layers 930 and 940 between bottom layer 920a and top layer 920b. Layers 930 and layers 940 may interleave with each other and may be formed alternately in the layer stack. In the illustrated example, bottom layer 920a, top layer 920b, and layers 940 may include a high refractive index material, while layer 930 may have a low refractive index. In some embodiments, bottom layer 920a, top layer 920b, and layers 940 may include a low refractive index material, while layer 930 may have a high refractive index. The optical thickness of each layer 930 or 940 may be about a quarter of a central wavelength λ₀ of optical notch filter 900, which may be outside of the emission spectral band of the LED. The optical thickness of each of bottom layer 920a and top layer 920b may be different from the quarter wavelength of optical notch filter 900. In one example, bottom layer 920a and top layer 920b may both have an optical thickness about 1.35 times of a quarter of the central wavelength λ₀ of optical notch filter 900.

FIG. 9B includes a curve 950 illustrating the reflectivity of the example of optical notch filter 900 of FIG. 9A as a function of the wavelength of surface-normal incident light (referred to herein as the reflectance spectra). The central wavelength λ₀ of optical notch filter 900 may be determined by the optical thickness of layers 930 and 940. The lower edge wavelength λₑ of optical notch filter 900 may be determined by:

$${λ}_{e} = \frac{{λ}_{0}}{1 - \frac{2}{π} {sin}^{- 1} ( \frac{( {n}_{H} - {n}_{L} )}{( {n}_{H} + {n}_{L} )} )} , \qquad ( 1 )$$

where n_{H} may be the refractive index of the high refractive index material, and n_{L} may be the refractive index of the low refractive index material. In the illustrated example, the central wavelength λ₀ of optical notch filter 900 may be in the red light band (e.g., at about 640 nm), and the lower edge wavelength λₑ of optical notch filter 900 may be between the blue light band and the green light band (e.g., at about 500-520 nm). Thus, the reflection wavelength range of optical notch filter 900 may cover the red light band and at least a portion of green light band, but not the blue light band. Therefore, optical notch filter 900 may be a notch filter for red and green light, and may be an angle-dependent optical filter for an LED that emits blue light, for example, with wavelengths 4 between about 425 nm and about 475 nm.

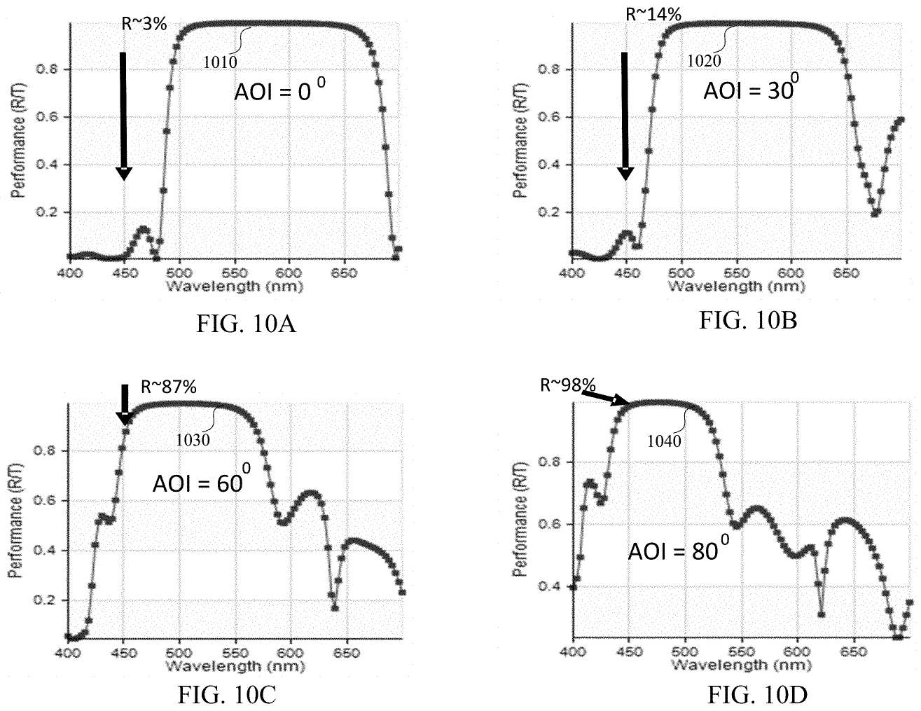

FIGS. 10A-10D illustrate reflectance spectra of an example of an optical notch filter as a function of the incident angle of the incident light. In the illustrated example, the optical notch filter may have a central wavelength close to about 600 nm and a reflection band width about 180 nm, and thus may be a notch filter for red and green light.

FIG. 10A includes a curve 1010 illustrating the reflectivity of the optical notch filter as a function of the wavelength of surface-normal incident light. FIG. 10A shows that, for surface-normal incident light with wavelengths around 450 nm (blue light), the reflectance of the optical notch filter may be very low (e.g., about 3% or lower). Therefore, the optical notch filter may allow surface-normal incident blue light emitted by a blue light LED (e.g., with wavelengths between about 425 nm and about 475 nm) to pass through with little or no loss.

FIG. 10B includes a curve 1020 illustrating the reflectivity of the optical notch filter as a function of the wavelength of incident light with an incident angle about 30°. FIG. 10B shows that, for incident light with wavelengths around 450 nm (blue light) and incident angles around 30°, the reflectance of the optical notch filter may be low (e.g., about 14%). Therefore, the optical notch filter may allow a majority of the incident blue light with incident angles around 30° to pass through with a small loss.

FIG. 10C includes a curve 1030 illustrating the reflectivity of the optical notch filter as a function of the wavelength of incident light with an incident angle about 60°. FIG. 10C shows that, for incident light with wavelengths around 450 nm (blue light) and incident angles around 60°, the reflectance of the optical notch filter may be high (e.g., about 87%). Therefore, the optical notch filter may reflect a majority of the incident blue light with incident angles around 60°.

FIG. 10D includes a curve 1040 illustrating the reflectivity of the optical notch filter as a function of the wavelength of incident light with an incident angle about 80°. FIG. 10D shows that, for incident light with wavelengths around 450 nm (blue light) and incident angles around 80°, the reflectance of the optical notch filter may be very high (e.g., about 98% or higher). Therefore, the optical notch filter may reflect substantially all the incident blue light with incident angles around 80° or higher.

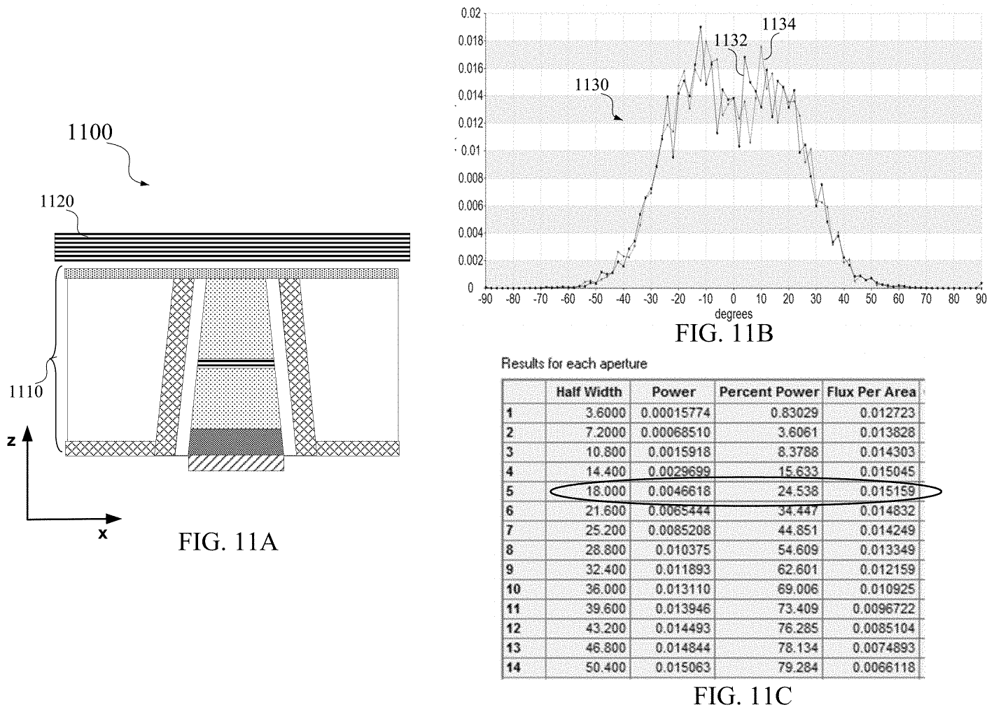

FIG. 11A illustrates an example of an LED device 1100 with an angle-dependent optical filter 1120 according to certain embodiments. In LED device 1100, angle-dependent optical filter 1120 may be placed on an array of LEDs 1110. Angle-dependent optical filter 1120 may be an example of optical notch filter 900. The array of LEDs 1110 may have a structure similar to LED device 800. Thus, the array of LEDs 1110 and angle-dependent optical filter 1120 are not described in detail again in this section. The specific example of LEDs shown in FIG. 11A are for illustrative purposes only and are not intended to limit the scope of the invention to the specific example. Angle-dependent optical filter 1120 may also be used to collimate light beams emitted by other LEDs with different structures, orientations, mesa shapes, and/or layer stacks.

FIG. 11B illustrates a simulated beam intensity profile 1130 of a light beam emitted by an LED of the example of LED device 1100 of FIG. 11A. Curves 1132 and 1134 in FIG. 11B show the simulated beam intensity as a function of the emission angle in the x-z plane and the y-z plane, respectively. In the illustrated example, the LED device may include an array of micro-LEDs with a pitch about 4 μm. As illustrated, the light beam emitted by an LED of LED device 1100 (after passing through angle-dependent optical filter 1120) may include light with smaller emission angle (divergence angle), compared with the light beam emitted by LED device 800 as shown in FIG. 8B. The intensity of the light emitted at emission angles θ between about ±20° may be high and relatively flat, and the intensity of the light emitted at emission angles θ beyond about ±40° may be very low. Therefore, compared with the light beams emitted by LED device 800 as shown by simulated beam intensity profile 860, the light beams emitted by LED device 1100 may have a smaller emission cone and a more uniform intensity within the smaller emission cone.

FIG. 11C illustrates the total optical energy and average intensity within different emission cones of a light beam emitted by an LED of LED device 1100 of FIG. 11A. As shown in FIG. 11C, the total optical power of the emitted light with emission angles within ±18° (which is the light that may be accepted by the display optics of a near-eye display system) is about 0.0047 units and about 24.5% of the total power of the light emitted from the LED, much higher than the about 0.0032 units and about 8.5% of the total power of the emitted light beam shown in FIG. 8C. Therefore, the overall efficiency of the display system may be improved significantly compared with the example shown in FIGS. 8A-8C.

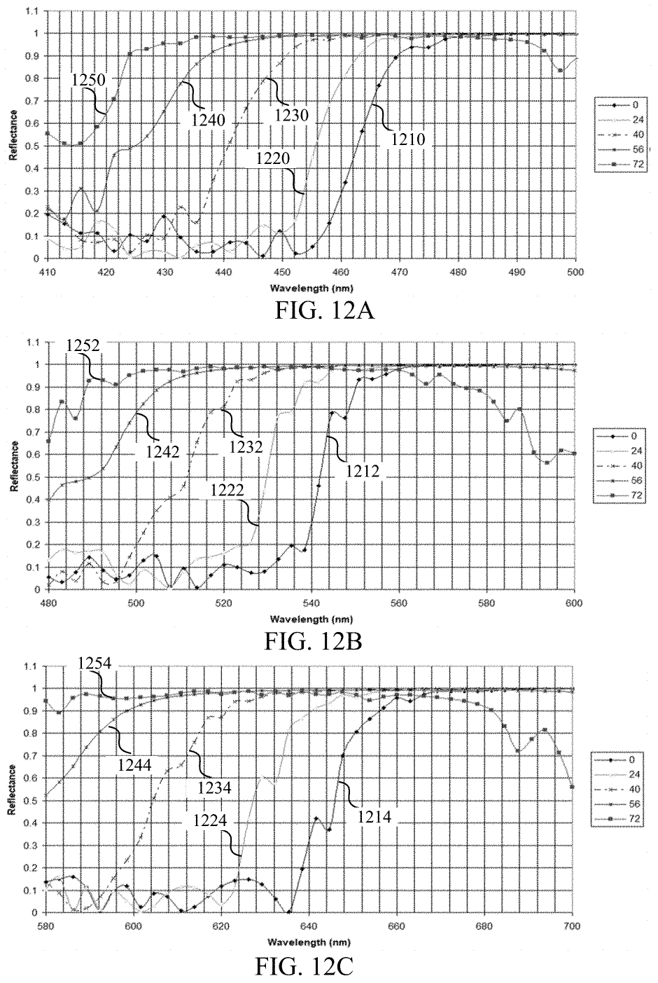

FIG. 12A illustrates reflectance spectra of an example of an angle-dependent optical filter for blue light as a function of the incident angle of the incident light. The angle-dependent optical filter may be an example of the optical notch filters or angle-dependent optical filters shown in FIGS. 9A-11C. In the example shown in FIG. 12A, the central wavelength of the optical notch filter used to implement the angle-dependent optical filter may be about 520 nm. For illustration purposes and for clarity, only a portion of the reflectance spectra of the angle-dependent optical filter, namely the left portion (e.g., the shorter wavelength portion) of the reflectance spectra, is shown in FIG. 12A. In FIG. 12A, curves 1210, 1220, 1230, 1240, and 1250 show the reflectance spectra of the angle-dependent optical filter for incident light with incident angles about 0°, about 24°, about 40°, about 56°, and about 72°, respectively. As shown in FIG. 12A, in general, the reflectance spectra of the angle-dependent optical filter may move substantially toward shorter wavelengths when the AOI increases.

In the example illustrated in FIG. 12A, when blue light (e.g., with wavelengths around 450 nm) is incident on the angle-dependent optical filter with incidence angles within a first AOI range (e.g., less than about 24°, less than about 20°, or less than about 18°), the wavelength range of the light emitted from the LED (e.g., with a peak wavelength about 450 nm and a full-width half-maximum (FWHM) range about 20-50 nm) may be within the transmission wavelength range (e.g., where the reflectance may be less than a predetermined amount, such as below about 20% or 15%) of the angle-dependent optical filter. Accordingly, the angle-dependent optical filter may mostly transmit light within a certain narrow wavelength range (e.g., the blue light) incident on the angle-dependent optical filter at AOIs within the first AOI range (e.g., less than about 25°, about 20°, or about 18°).

When the blue light is incident on the angle-dependent optical filter at AOIs within a second AOI range (e.g., larger than about 25°, 30°, or 40°), at least a portion of the wavelength range of the light emitted from the LED may fall within the reflection wavelength range of the reflectance spectra, and thus may be reflected by the angle-dependent optical filter with high reflectance (e.g., greater than about 85% or higher). As a result, the angle-dependent optical filter may have a low transmissivity for incident light within the narrow wavelength range (e.g., the blue light) and with AOIs within the second AOI range (e.g., greater than about 25°, 30°, or) 40°.

When the AOI of the incident light is greater than certain value (e.g., about 56° or larger in the illustrated example), the wavelength range of the light emitted from the LED (e.g., light with a peak wavelength about 450 nm and an FWHM about 20-50 nm) may fall within the reflection wavelength range of the angle-dependent optical filter. Accordingly, the angle-dependent optical filter may mostly reflect (with a reflectance greater than about 90% or close to about 100%) incident light within a certain narrow wavelength range (e.g., the blue light) incident on the angle-dependent optical filter at AOIs larger than the certain value (e.g., about 56° or larger in the illustrated example). Therefore, the emitted light after passing through the angle-dependent optical filter may not include light with large emission angles

FIG. 12B illustrates reflectance spectra of an example of an angle-dependent optical filter for green light as a function of the incident angle of the incident light. In the illustrated example, the central wavelength of the optical notch filter used to implement the angle-dependent optical filter may be about 620 nm. For illustration purposes and for clarity, only a portion of the reflectance spectra of the angle-dependent optical filter, namely a left portion (e.g., the shorter wavelength portion) of the reflectance spectra, is shown in FIG. 12B. In FIG. 12B, curves 1212, 1222, 1232, 1242, and 1252 correspond to the reflectance spectra of the angle-dependent optical filter for incident light with incident angles about 0°, about 24°, about 40°, about 56°, and about 72°, respectively. As shown in FIG. 12B, in general, the reflectance spectra of the angle-dependent optical filter may move substantially toward shorter wavelengths when the AOI increases. Thus, for green light emitted by a green light LED (with wavelengths around 520 or 530 nm), the reflectance may gradually increase from about 0% to about 100% as the incident angle of the green light incident on the angle-dependent optical filter increases from about 0° to about 56° or larger.

FIG. 12C illustrates reflectance spectra of an example of an angle-dependent optical filter for red light as a function of the incident angle of the incident light. In the illustrated example, the central wavelength of the optical notch filter used to implement the angle-dependent optical filter may be about 750 nm. For illustration purposes and for clarity, only a portion of the reflectance spectra of the angle-dependent optical filter, namely the left portion (e.g., the shorter wavelength portion) of the reflectance spectra, is shown in FIG. 12C. In FIG. 12C, curves 1214, 1224, 1234, 1244, and 1254 correspond to the reflectance spectra of the angle-dependent optical filter for incident light with incident angles about 0°, about 24°, about 40°, about 56°, and about 72°, respectively. As shown in FIG. 12C, in general, the reflectance spectra of the angle-dependent optical filter may move substantially toward shorter wavelengths when the AOI increases. Thus, for red light emitted by a red light LED (with wavelengths around 620 or 630 nm), the reflectance may gradually increase from about 0% to about 100% as the incident angle of the red light incident on the angle-dependent optical filter increases from about 0° to about 40° or larger.

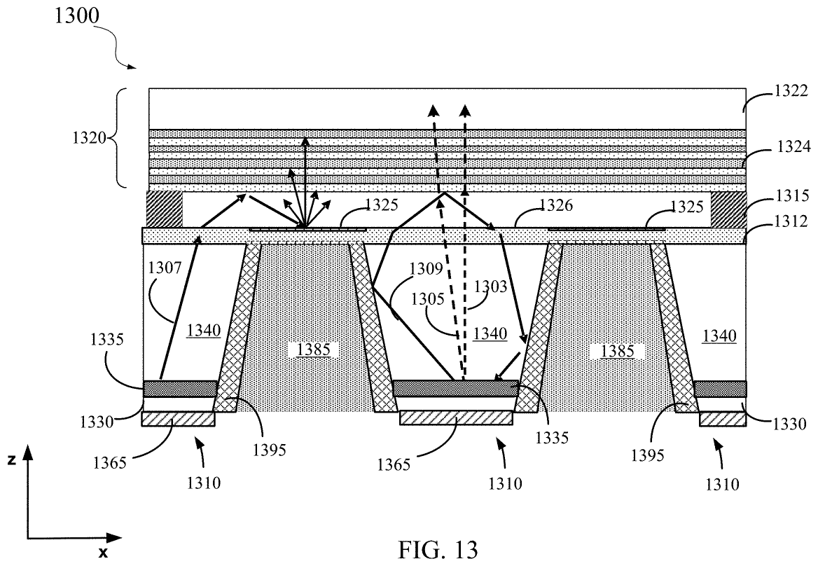

FIG. 13 illustrates an example of an LED device 1300 including an angle-dependent optical filter 1320 optically coupled to an array of LEDs 1310 according to certain embodiments. Angle-dependent optical filter 1320 may be coupled to the array of LEDs 1310 through, for example, a spacer 1315. Therefore, there may be an air gap between the array of LEDs 1310 and angle-dependent optical filter 1320. As described above with respect to, for example, FIGS. 9A and 11A, angle-dependent optical filter 1320 may include a substrate 1322 and a plurality of optical thin-film layers 1324 made of semiconductor or dielectric materials. In the illustrated example, to further increase the light extraction efficiency and the intensity of the light emitted by LEDs 1310, LED device 1300 may also include a reflective surface 1325 (e.g., a rough reflective surface) between LEDs 1310 and angle-dependent optical filter 1320 (e.g., formed on a surface of a transparent conductive layer 1312 such as an ITO layer). Reflective surface 1325 may scatter at least a portion of the light reflected by angle-dependent optical filter 1320 back to angle-dependent optical filter 1320 at different incident angles. The scattered light with small incident angles may be transmitted by angle-dependent optical filter 1320, and thus the overall light extraction efficiency may be improved.

LEDs 1310 in LED device 1300 may be examples of the light emitters in light sources 510, 540, and 642, and LEDs 700 and 705. It is noted that the specific examples of LEDs described herein are for illustration purposes only and are not intended to limit the scope of the invention to the specific examples. Any suitable LEDs may use the angle-dependent optical filter disclosed herein to achieve light collimation and improve light extraction efficiency. In the illustrated example, each LED 1310 may include a mesa structure that includes a first semiconductor layer 1330 (e.g., p-doped or n-doped GaN layer), an active region 1335 (e.g., including one or more quantum wells) configured to emit light, a second semiconductor layer 1340 (e.g., n-doped or p-doped GaN layer), a first electrical contact 1365 (e.g., a p-contact) that may include a back reflector, and a sidewall reflector 1395 that may include a dielectric layer (e.g., a passivation layer such as SiO₂ or SiN) and a metal layer (e.g., an Al layer). The array of LEDs 1310 may also include second electrical contacts 1385 (e.g., n-contacts) between the mesa structures and connected to transparent conductive layer 1312, which may be a common electrode, such as a common cathode.

Active region 1335 may emit light in a narrow wavelength range (e.g., about 20 to about 40 nm), such as red, green, or blue light. For example, active region 1335 may be configured to emit blue light having a peak wavelength about 450 nm and an FWHM wavelength range about 20 nm to about 40 nm. Light emitted in active region 1335 may be directed to a light emitting surface 1326 at different incident angles, for example, by the back reflector at first electrical contact 1365 and sidewall reflector 1395. At light emitting surface 1326, some light (e.g., as shown by light rays 1303, 1305, 1307, and 1309) may be refracted out of the array of LEDs 1310, while some light with large incident angles may be reflected back due to total internal reflection (TIR) at the interface between transparent conductive layer 1312 and air. In some embodiments, light emitting surface 1326 may have a rough surface to diffuse light, thereby reducing reflection caused by the TIR and improving the light extraction efficiency. As described above with respect to FIG. 8A, the light that exits an LED 1310 may include light with emission angles θ between ±90° with respect to the surface-normal direction of light emitting surface 1326, and the intensity profile of the emitted light beam may be similar to simulated beam intensity profile 860.

Angle-dependent optical filter 1320 may be positioned on the array of LEDs 1310 through spacer 1315. Therefore, light emitted by LED 1310 may be incident on angle-dependent optical filter 1320 at different angles of incidence (AOIs) between ±90°. As described above, for surface-normal incident light, angle-dependent optical filter 1320 may be a band-stop filter (e.g., a notch filter) with a stop band (reflection band) at a central wavelength higher than the wavelengths of the light emitted by active region 1335, such that the wavelengths of the emitted light may be outside of the stop band for surface-normal incident light. Therefore, angle-dependent optical filter 1320 may transmit surface-normal incident light emitted from LED 1310.

As described above with respect to FIGS. 10A-10D and 12A-12C, the reflection wavelength range of angle-dependent optical filter 1320 may vary with the AOI of the light incident on angle-dependent optical filter 1320. When light emitted from the LED (e.g., light with a peak wavelength about 450 nm and an FWHM range about 20-50 nm) is incident on angle-dependent optical filter 1320 with incidence angle within a first AOI range (e.g., less than about 30°, 25°, 20°, or 18°) as shown by, for example, light rays 1303 and 1305, the wavelength range of the light emitted from the LED may be mostly within the transmission wavelength range of the reflectance spectra, and thus angle-dependent optical filter 1320 may mostly transmit the light incident on angle-dependent optical filter 1320 at AOIs within the first AOI range as shown by light rays 1303 and 1305. When light emitted from the LED is incident on angle-dependent optical filter 1320 at AOIs within a second AOI range (e.g., larger than about 25°, 30°, or 40°) as shown by light rays 1307 and 1309, at least a portion or all of the wavelength range of the light emitted by the LED may fall within the reflection wavelength range of the reflectance spectra, and thus may be reflected by the angle-dependent optical filter with high reflectance (e.g., greater than about 85% or higher). As a result, angle-dependent optical filter 1320 may mostly reflect the incident light with AOIs within the second AOI range.

In some embodiments, the first AOI range for angle-dependent optical filter 1320 may be from 0 to about 15 degrees, from 0 to about 18 degrees, from 0 to about 20 degrees, from 0 to about 24 degrees, from 0 to about 26 degrees, from 0 to about 30 degrees, and the like, depending on the desirable emission angle. In some embodiments, the second AOI range for angle-dependent optical filter 1320 may be from about 25 degrees to 90 degrees, from about 30 degrees to 90 degrees, from about 35 degrees to 90 degrees, from about 37 degrees to 90 degrees, from about 39 degrees to 90 degrees, from about 40 degrees to 90 degrees, and the like.

Some incident light with large AOIs may be reflected by angle-dependent optical filter 1320 and may reach reflective surface 1325. Reflective surface 1325 may be formed on a top or bottom surface of transparent conductive layer 1312 (e.g., an ITO layer) or may be formed on a surface of second electrical contacts 1385. In some embodiments, reflective surface 1325 may include one or more metal or metal alloy materials, such as aluminum (Al), silver (Ag), gold (Au), platinum (Pt), titanium (Ti), copper (Cu), or any combination thereof. Reflective surface 1325 may include a rough surface and thus may scatter at least a portion of the light reflected by angle-dependent optical filter 1320 back to angle-dependent optical filter 1320. For example, as illustrated in FIG. 13, light ray 1307 may be incident on angle-dependent optical filter 1320 at a large AOI, and thus most light of light ray 1307 may be reflected by angle-dependent optical filter 1320. The reflected portion of light ray 1307 may be incident on reflective surface 1325, and reflective surface 1325 may reflectively scatter the reflected portion of light ray 1307 back toward angle-dependent optical filter 1320. The portion of the scattered light incident on angle-dependent optical filter 1320 at small incident angles may be transmitted by angle-dependent optical filter 1320, and thus the light extraction efficiency may be improved due to the recycling of the reflected light. As such, the array of LEDs 1310 may have an increased light emitting area and increased output optical power, and may be used as light sources for illumination

Light emitting surface 1326 of each LED 1310 may not have a reflective surface similar to reflective surface 1325, such that light may be emitted out of LED 1310 through light emitting surface 1326. Some incident light with large AOIs may be reflected by angle-dependent optical filter 1320 and may reach light emitting surface 1326, and light emitting surface 1326 may allow the reflected light to pass through and enter epitaxial layers of LED 1310. For example, as illustrated in FIG. 13, light ray 1309 emitted by LED 1310 may be coupled out of an LED 1310 and directed to angle-dependent optical filter 1320 at a large AOI. After being reflected by angle-dependent optical filter 1320, light in light ray 1309 may pass through light emitting surface 1326 and re-enter LED 1310. In some embodiments, the light that re-enters LED 1310 may be reflected by the back reflector and/or sidewall reflector 1395 back toward light emitting surface 1326, and may be incident on angle-dependent optical filter 1320 at a smaller AOI and thus may be transmitted by angle-dependent optical filter 1320. In some embodiments, light emitting surface 1326 (or the top surface of second semiconductor layer 1340 of LED 1310) may have a rough surface. The rough surface may transmissively diffuse incident light to reduce reflection caused by total internal reflection (thereby increasing the light extraction efficiency from LED 1310), and may also change the propagating directions of the light reflected by angle-dependent optical filter 1320, where some of the light entering LED 1310 may be reflected by the back reflector and/or sidewall reflector 1395 to eventually reach angle-dependent optical filter 1320 with a small AOI and thus may be transmitted by angle-dependent optical filter 1320.

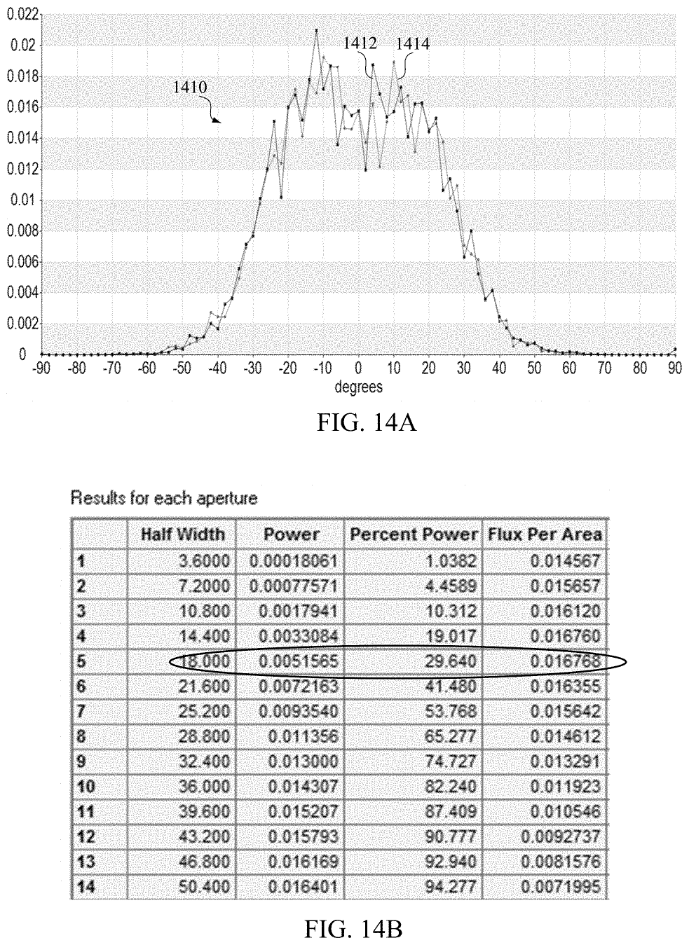

FIG. 14A illustrates a simulated beam intensity profile 1410 of a light beam emitted by LED device 1300 of FIG. 13. Curves 1412 and 1414 in FIG. 14A show the simulated beam intensity as a function of the emission angle in the x-z plane and the y-z plane, respectively. In the illustrated example, the LED device may include an array of micro-LEDs with a pitch about 4 μm. As illustrated, the light beam emitted from a micro-LED in LED device 1300 (after passing through angle-dependent optical filter 1320) may include light with smaller emission angles, compared with the light beam emitted by LED device 800 as shown in FIG. 8B. For example, the FWHM emission angle of the light beam emitted by LED device 1300 may be within ±30°. The intensity of the light emitted at emission angles θ between about ±20° may be high and relatively flat, and the intensity of the light emitted at emission angles θ beyond about ±40° may be very low. Therefore, compared with the light beam emitted by LED device 800 as shown by simulated beam intensity profile 860, the light beam emitted by LED device 1300 may have a smaller emission cone and a more uniform and higher intensity within the smaller emission cone. In addition, compared with the light beam emitted by an LED of LED device 1100 as shown in FIG. 11B, the light beam emitted by an LED in LED device 1300 may have a higher intensity in the small emission cone (e.g., within about ±20°).

FIG. 14B illustrates the total optical energy and average intensity within different emission cones of a light beam emitted by LED device 1300 of FIG. 13. As shown in FIG. 14B, the total optical power of the emitted light with emission angles within ±18° (which is the light that may be accepted by the display optics of a near-eye display system) is about 0.0052 units and is about 29.6% of the total power of the light emitted from the LED, higher than the about 0.0047 units and about 24.5% of the total power of the emitted light beam shown in FIG. 11C. Therefore, the absolute power and the percentage of the light within the ±18° emission cone may both be increased. As such, both the light extraction efficiency of the LED and the degree of collimation of the emitted light beam may be improved. As a result, the overall efficiency of the system may be improved compared with the example shown in FIGS. 8A-8C and the example shown in FIGS. 11A-11C.

As described above, the angle-dependent optical filters disclosed herein may have a top layer and a bottom layer that sandwich other thin-film layers of the optical film stack. The optical thickness of the top layer of the optical film stack and the optical thickness of the bottom layer of the optical film stack may be different from the uniform optical thickness of other thin-film layers, such as about a quarter of the wavelength of the central wavelength of the notch filter. The wavelength of the central wavelength of the notch filter may be longer than the wavelength of the incident light, and the wavelength of the incident light may be outside of the reflection wavelength range of the notch filter. The top layer and the bottom layer of the optical film stack may have an optical thickness greater or shorter than a quarter of the central wavelength of the notch filter. The top layer and the bottom layer of the optical film stack may include a high refractive index material or a low refractive index material.

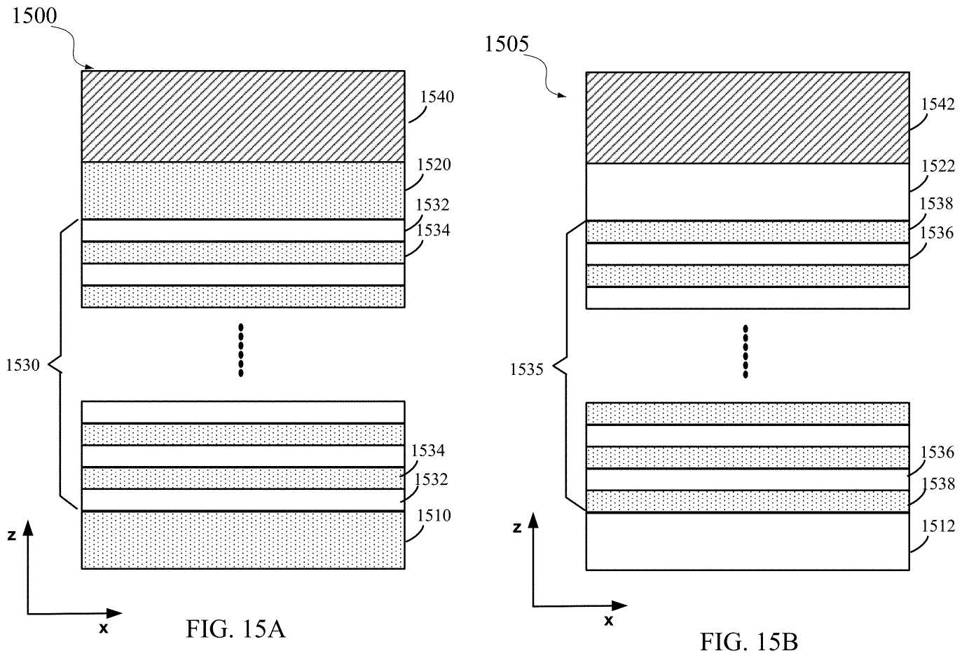

FIGS. 15A and 15B illustrate cross-section views of examples of angle-dependent optical filters 1500 and 1505, respectively, according to certain embodiments. As illustrated, angle-dependent optical filters 1500 and 1505 may be similar to optical notch filter 900 shown in FIG. 9A. Angle-dependent optical filters 1500 and 1505 may have similar structures (e.g., including a top layer, a bottom layer, a stack of optical film layers with alternating refractive indices between the top layer and the bottom layer, and a substrate). In the following descriptions, angle-dependent optical filter 1500 may be described in detail, whereas, for angle-dependent optical filter 1505, only its differences from angle-dependent optical filter 1500 may be described in detail below.

In the example illustrated in FIG. 15A, angle-dependent optical filter 1500 may include a top layer 1510, a bottom layer 1520, and a stack of optical film layers 1530 formed on a substrate 1540, where the stack of optical film layers 1530 may be between top layer 1510 and bottom layer 1520. Substrate 1540 may include any suitable transparent optical material on which top layer 1510, bottom layer 1520, and the stack of optical film layers 1530 may be formed, such as glass, quartz, fused silica, crystal, or sapphire. The stack of optical film layers 1530 may include a set of first optical film layers 1532 interleaved with a set of second optical film layers 1534. The stack of optical film layers 1530 may start and end with the same kind of optical film layers from the bottom to the top (e.g., in the z direction). In some embodiments as illustrated in FIG. 15A, the stack of optical film layers 1530 may start and end with first optical film layers 1532 in the z direction. Thus, the optical film layer at the bottom and the optical film layer at the top of the stack of optical film layers 1530 may both be first optical film layers 1532, and second optical film layers 1534 may be in between and may interleave with first optical film layers 1532. In other words, except for the bottom layer and the top layer of first optical film layers 1532 in the stack of optical film layers 1530, each first optical film layer 1532 is sandwiched by two adjacent second optical film layers 1534, and each second optical film layer 1534 is sandwiched by two adjacent first optical film layers 1532. Accordingly, the stack of optical film layers 1530 may include an odd number of optical film layers (e.g., including 11 layers, 13 layers, 15 layers, 17 layers, or 19 layers).

First optical film layers 1532 may include a first material characterized by a first refractive index, and second optical film layers 1534 may include a second material characterized by a second refractive index different from the first refractive index. In the example shown in FIG. 15A, the first refractive index of the first material in first optical film layers 1532 may be higher than the second refractive index of the second material in second optical film layers 1534. In one example, first optical film layers 1532 may include gallium nitride (GaN) (e.g., with a refractive index about 2.44), and second optical film layers 1534 may include porous GaN (e.g., GaN with 70% porosity and with a refractive index about 1.58). The porosity of the porous GAN may be determined based on the desired refractive index n_{P} of the porous GaN, which may be determined according to:

n_{P}=\sqrt{(1−p)×n_{GaN}_{₂}+p}, (2)

where n_{GaN} is the refractive index of GaN and p is the porosity of porous GaN.

In some embodiments, top layer 1510 and bottom layer 1520 may include a material different from the material of the optical film layers next to top layer 1510 and bottom layer 1520. For example, as illustrated in FIG. 15A, top layer 1510 and bottom layer 1520 may both include a material different from the material of first optical film layers 1532. In some embodiments, second optical film layers 1534, top layer 1510, and bottom layer 1520 may include a same material or may include different materials having similar refractive indices. In some embodiments, top layer 1510 and bottom layer 1520 may include a material different from the material of first optical film layers 1532 and the material of second optical film layers 1534 (e.g., a material having a refractive index different from the refractive index of the first material included in first optical film layers 1532 and the refractive index of the second material included in second optical film layers 1534). For example, top layer 1510 and bottom layer 1520 may include porous GaN having a porosity different from the porosity of the GaN material included in second optical film layers 1534.

As described above, the thickness of each first optical film layer 1532 and the thickness of each second optical film layer 1534 may be determined based on a desired wavelength λ₀ of the central wavelength of a notch filter, where wavelength λ0 may be different from (e.g., longer than) the wavelengths of the light emitted by the LED and the wavelengths of the light emitted by the LED may be outside of (e.g., shorter than) the reflection wavelength range of the notch filter for surface-normal incident light. In some embodiments, wavelength λ0 may be determined based on simulation or experiment results (e.g., the wavelength λ0 that may result in the best light extraction efficiency and/or the best collimation). For example, when the light emitted by the LED is blue light (e.g., with a peak wavelength about 450 nm and a FWHM about 20-50 nm), λ₀ may be set to 530 nm, 540 nm, 550 nm, or the like, such that the wavelength range of the light emitted by the LED (e.g., 450 nm±20 nm) may be outside of the reflection wavelength range of the notch filter, such as shorter than the lower edge wavelength λₑ of the notch filter. The thickness of each of first optical film layers 1532 and second optical film layers 1534 may be determined such that optical thickness of each optical film layer is about λ₀/4. Thus, the thickness t₁ of each first optical film layer 1532 may be determined according to:

$${t}_{1} = \frac{{λ}_{0}}{4 {n}_{H}} . \qquad ( 3 )$$

Similarly, the thickness t2 of each second optical film layer 1534 may be determined according to:

$${t}_{2} = \frac{{λ}_{0}}{4 {n}_{L}} . \qquad ( 4 )$$

To achieve the desired angle-dependent reflection characteristics (e.g., transmitting light at shorter wavelengths and reflect light at longer wavelengths for each AOI), top layer 1510 and bottom layer 1520 may have a different thickness than the thickness of first optical film layers 1532 and the thickness of second optical film layers 1534. In some embodiments, top layer 1510 and bottom layer 1520 may have a thickness thinner than the thickness of each first optical film layer 1532 and the thickness of each second optical film layer 1534. For example, the thickness of top layer 1510 and bottom layer 1520 may be selected such that the optical thickness of each of top layer 1510 and bottom layer 1520 may be about λ₀/8. Thus, the thickness t_{T} of top layer 1510 may be determined according to:

$${t}_{T} = \frac{{λ}_{0}}{8 {n}_{T}} , \qquad ( 5 )$$

where n_{T} is the refractive index of top layer 1510. The thickness is of bottom layer 1520 may be determined according to:

$${t}_{B} = \frac{{λ}_{0}}{8 {n}_{B}} , \qquad ( 6 )$$

where n_{B} is the refractive index of bottom layer 1520 and may be similar to n_{T}.

In some embodiments, top layer 1510 and bottom layer 1520 may each have a thickness greater than the thickness of first optical film layer 1532 and the thickness of second optical film layer 1534. For example, the thickness of each of top layer 1510 and bottom layer 1520 may be determined such that the optical thickness of each of top layer 1510 and bottom layer 1520 may be about 1.35/4 λ₀. Therefore, the thickness t_{T} of top layer 1510 may be determined according to:

$${t}_{T} = \frac{1.35 {λ}_{0}}{4 {n}_{T}} . \qquad ( 7 )$$

The thickness is of bottom layer 1520 may be determined according to:

$${t}_{B} = \frac{1.35 {λ}_{0}}{4 {n}_{B}} . \qquad ( 8 )$$

In some embodiments, top layer 1510 and bottom layer 1520 may have different optical thicknesses.

It is noted that the materials included in top layer 1510, bottom layer 1520, first optical film layers 1532, and second optical film layers 1534, and the thicknesses of top layer 1510 and bottom layer 1520 are not limited to the examples described above. Any other suitable optical thin film materials (e.g., oxides, sulfides, fluorides, metals, etc.) may be used in top layer 1510, bottom layer 1520, first optical film layers 1532, and second optical film layers 1534. Top layer 1510 and bottom layer 1520 may have other optical thicknesses that may be different from a quarter of wavelength λ₀.

Angle-dependent optical filter 1505 shown in FIG. 15B may have a structure, a layer stack, and individual layer thicknesses similar to those of angle-dependent optical filter 1505. In the illustrated example, angle-dependent optical filter 1500 may include a substrate 1542 (which may be similar to substrate 1540) and an optical film stack formed on substrate 1542. The optical film stack may include a bottom layer 1522, a top layer 1512, and a stack of optical film layers 1535 between bottom layer 1522 and top layer 1512. The stack of optical film layers 1535 may include a set of first optical film layers 1538 interleaved with a set of second optical film layers 1536. The thicknesses of top layer 1512, each first optical film layer 1538, each second optical film layer 1536, and bottom layer 1522 may be similar to the thicknesses of top layer 1510, each first optical film layer 1532, each second optical film layer 1534, and bottom layer 1520, respectively. In the example illustrated in FIG. 15B, the stack of optical film layers 1535 may start and end with first optical film layers 1538 from the bottom to the top (e.g., in the z direction). In other words, the optical film layer at the bottom and the optical film layer at the top of the stack of optical film layers 1535 may both be first optical film layers 1538, and second optical film layers 1536 may interleave with first optical film layers 1538. Top layer 1512 and bottom layer 1522 may both include a material different from the material of first optical film layers 1538, and may include a material same as or different from the material of second optical film layers 1536. For example, top layer 1512, bottom layer 1522, and second optical film layers 1536 may have a higher refractive index, while first optical film layer 1538 may have a lower refractive index. In one example, top layer 1512 and bottom layer 1522 may both include GaN, the same material as the material of second optical film layers 1536, while first optical film layers 1538 may include porous GaN.

GaN layers with different porosities may be formed by epitaxially growing GaN layers with different doping densities of, for example, n-type dopants (e.g., Si or Ge), and selectively porosifying, for example, the GaN layers with a higher doping density (e.g., about 1×10¹⁹ cm⁻³ to about 2×10²⁰ cm⁻³). The GaN layers with the higher doping density may be made porous through, for example, an electrochemical (EC) etching or photo-electrochemical etching (PEC) process. In one example, a process for forming porous gallium nitride may include exposing heavily-doped GaN layers to an electrolyte that includes an etchant, such as an acid or alkali solution (e.g., Oxalic acid (C₂H₂O₄), HNO₃, HF, HCl, H₂O₂, H₂SO₄, NaOH, or KOH). An electrical bias may then be applied between the etchant and the heavily-doped gallium nitride. The heavily-doped GaN layers may be etched, for example, according to 2GaN+6h⁺→2Ga³⁺+N₂, where the Ga³⁺ ions may dissolve in the electrolyte. The EC etching process may be carried out in a constant voltage mode (e.g., with a DC bias of a few volts), and may be controlled by monitoring the etching current using a current meter. The EC etching process can be carried at room temperature without using UV illumination. The EC etching process may include the oxidation of the heavily doped GaN layers by the localized injection of holes due to the application of a positive DC bias. The oxidized layers may be locally dissolved in an acid-based electrolyte, thereby forming a mesoporous structure. The etching process may end when the current monitored by the current meter drops to a baseline level, indicating that the heavily doped GaN layers have been etched and transformed into mesoporous GaN layers. The density and size of the porosity may be controlled by, for example, varying the concentration of the solution, the applied current, the etching duration, the doping density, the thickness of the heavily-doped GaN layers, and the like.

In some embodiments, semiconductor material layers (e.g., GaN layers with different doping densities) used to form the angle-dependent optical filter may be grown on the light emitting side of the LED wafer, before or after growing the epitaxial layers of the p-i-n structure of the LED wafer. For example, semiconductor material layers with different doping densities may be grown on the p-side or the n-side of the p-i-n structure of the LED wafer. As such, the angle-dependent optical filter may be within the LEDs, rather than being made separately and then attached to the array of LEDs.

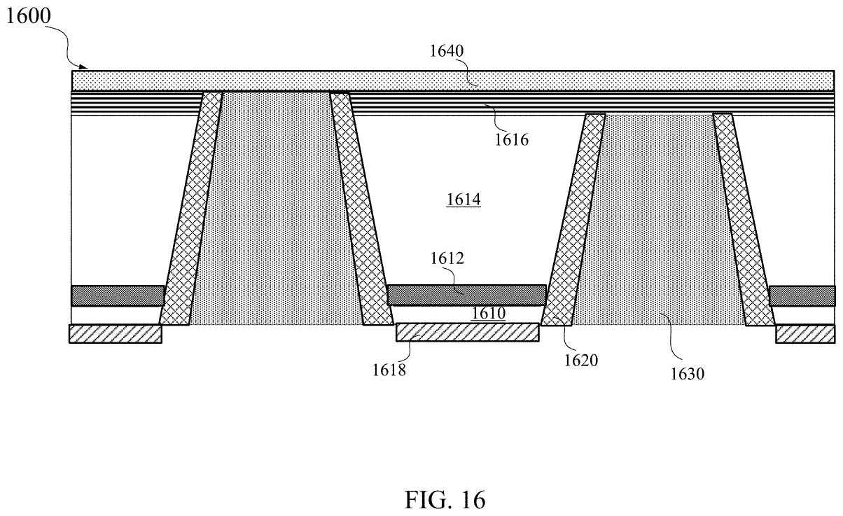

FIG. 16 illustrates a cross-sectional view of an examples of an LED device 1600 including an internal angle-dependent optical filter 1616 according to certain embodiments. LED device 1600 may include an array of LEDs (e.g., micro-LEDs). Each LED may include a mesa structure that may include semiconductor epitaxial layers, such as semiconductor layer 1610 (e.g., a p-doped GaN layer including dopants such as Mg, Ca, Zn, or Be, or an n-doped GaN layer including dopants such as Si or Ge), an active region 1612 (e.g., including InGaN/GaN quantum wells), and a second semiconductor layer 1614 (e.g., an n-doped GaN layer or a p-doped GaN layer). Each LED may also include a back reflector/electrical contact 1618, which may include a reflective metal such as Ag, Al, or Au and/or a metal layer (e.g., Cu, W, Ti, Ni, TiN, or a combination thereof) that forms a p-contact or p electrode at the bottom of the mesa structure. Each LED may further include a passivation layer 1620 (e.g., a dielectric material such as SiO₂ or SiN) that electrically isolates the LED from other LEDs, and one or more conductive materials 1630 (e.g., including a reflective metal such as Al, Ag, or Au, a barrier layer such as TiN or TaN, and a filler metal such as Al, Cu, W, Ti, or Au). The one or more conductive materials 1630 may form a sidewall reflector (e.g., including a reflective metal such as Al) that optically isolates the LED from other LEDs, and may also be used to connect drive circuits to a transparent conductive layer 1640 (e.g., an indium tin oxide layer) used as a common electrode (e.g., n-contact).

LED device 1600 may also include angle-dependent optical filter 1616 formed in epitaxially layers grown on the p-i-n structure of the LED. As shown in FIG. 16, angle-dependent optical filter 1616 may be a contiguous structure on the array of LEDs or may be etched and included in the mesa structures of individual LEDs. For example, as described above, a plurality of GaN layers may be grown before or after growing second semiconductor layer 1614. The GaN layers may include a first set of GaN layers with a low doping density (e.g., with n dopants) and a second set of GaN layers with a high doping density (e.g., with n dopants), where the thickness of each GaN layer may be selected as described with respect to, for example, FIGS. 9A, 9B, 15A, and 15B. The plurality of GaN layers may be porosified through, for example, an EC etching or PEC process described above, where the heavily doped GaN layers may be porosified to the desired porosity, while the lightly doped GaN layer may not be porosified. Therefore, GaN layers and porous GaN layers with desired refractive indices may be achieved and may form angle-dependent optical filter 1616 in or on each LED to collimate the light beam emitted by each LED. Because angle-dependent optical filter 1616 may be directly coupled to or within each LED and there may not be an air gap between angle-dependent optical filter 1616 and each LED, the thicknesses of the layers (e.g., the top and bottom layers) of angle-dependent optical filter 1616 may be different from the thicknesses of the layers of angle-dependent optical filter 1120 or 1320.

In some embodiments, the angle-dependent optical filter may include dielectric materials of different refractive indices, such as SiO₂, TiO₂, Ta₂O₅, Al₂O₃, HfO₂, and/or other oxides. The optical film stack may be formed on a transparent substrate and then placed on top of the LED light emitting surface (e.g., through a spacer). For example, the angle-dependent optical filter may be made by coating or depositing uniform layers of dielectric materials, such as SiO₂, TiO₂, Ta₂O₅, Al₂O₃, HfO₂, or other metal oxides that may be transparent to visible light on a transparent substrate, such as a glass or quartz substrate, using optical thin-film coating techniques such as various vapor deposition techniques (e.g., ion-assisted electron-beam evaporative deposition) or sputtering techniques (e.g., IBS, APS, or PARMS). The transparent substrate with the dielectric layers formed thereon may then be attached to the LED device, for example, using a spacer.

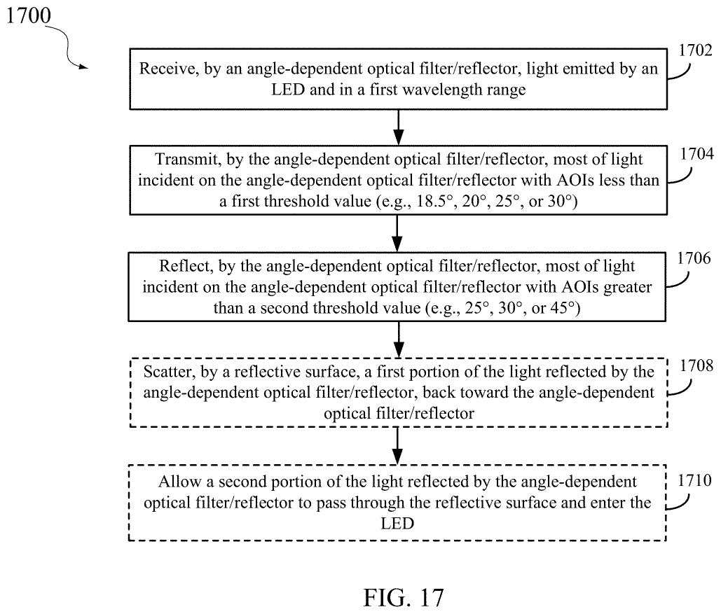

FIG. 17 includes a flowchart 1700 illustrating an example of a method of collimating light emitted by an LED using an angle-dependent optical filter/reflector according to certain embodiments. Operations described in flowchart 1700 are for illustration purposes only and are not intended to be limiting. In various implementations, modifications may be made to flowchart 1700 to add additional operations, omit some operations, merge some operations, simultaneously perform some operations, or split an operation. The method may be better understood along with descriptions of, for example, FIGS. 9A-16.

Operations in 1702 of flowchart 1700 may include receiving, by an angle-dependent optical filter/reflector, light emitted by an LED. The angle-dependent optical filter/reflector (e.g., optical notch filter 900 or angle-dependent optical filter 1120, 1320, 1500, 1505, or 1616) may be characterized by a reflection wavelength range that varies with the AOI of the light incident on the angle-dependent optical filter/reflector. The LED (e.g., LEDs 1110 or 1310, or LEDs in LED device 1600) may emit light in a first wavelength range (e.g., red, green, or blue light, such as light with a peak wavelength about 450 nm and a FWHM about 20 nm). As shown in and describe above with respect to FIGS. 10A-10D and 12A-12C, the transmission wavelength range and reflection wavelength range of the angle-dependent optical filter/reflector may vary with the AOI of the light incident on the angle-dependent optical filter/reflector.

In one example, the angle-dependent optical filter/reflector may include an optical notch filter, where the central wavelength of the optical notch filter may be outside of the first wavelength range, such as longer or shorter than the wavelengths of the light emitted by the LED. The angle-dependent optical filter/reflector may include, for example, a top layer, a bottom layer, and a layer stack between the top layer and the bottom layer, where the layer stack may include first optical film layers interleaved with second optical film layers. In some embodiments, the first optical film layers may include GaN with a porosity less than 10%, and the second optical film layers may include porous GaN with a porosity equal to or greater than 10%, such as about 20%, about 30%, about 40%, about 50%, about 60%, about 70%, about 80%, or higher. In some embodiments, the first optical film layers and the second optical film layers may include transparent dielectric materials, such as SiO₂, TiO₂, Ta₂O₅, Al₂O₃, HfO₂, or another metal oxide. The optical thickness (the shortest optical path length determined by the product of the physical thickness and the refractive index) of each optical film layer of the first optical film layers and the second optical film layers may be about a quarter of the central wavelength of the optical notch filter. The optical thickness of each of the bottom layer and the top layer may be different from a quarter of the central wavelength of the optical notch filter, such as about ⅛ of the central wavelength of the optical notch filter or about 1.35 times of the quarter wavelength of the central wavelength of the optical notch filter.

In 1704, the angle-dependent optical filter/reflector may transmit most of light received from the LED and with AOIs less than a first threshold value, as shown in, for example, FIGS. 10A, 10B, and 12A-12C. The first threshold value may be, for example, 18.5°, 20°, 25°, 30°, or larger. For light with AOIs less than the first threshold value, the reflection wavelength range of the angle-dependent optical filter/reflector may not include the first wavelength range or may only include a small portion of the first wavelength range. For example, for incident light with AOIs less than the first threshold value, most or all of the first wavelength range may be outside of the reflection wavelength range. As such, most of the light emitted from the LED and incident on the angle-dependent optical filter/reflector with AOIs less than the first threshold value may pass through the angle-dependent optical filter/reflector and be emitted out of the device.

In 1706, the angle-dependent optical filter/reflector may reflect most of light received from the LED and with AOIs greater than a second threshold value, such as, for example, 25°, 30°, 35°, 40°, 45°, or larger. For light with AOIs greater than the second threshold value, the reflection wavelength range of the angle-dependent optical filter/reflector may include a large portion or the full range of the first wavelength range, as shown in, for example, FIGS. 10C, 10D, and 12A-12C. As such, most of the light emitted from the LED and incident on the angle-dependent optical filter/reflector with AOIs greater than the second threshold value may be reflected by the angle-dependent optical filter/reflector back toward the LED.

Optionally, in 1708, a reflective surface between the LED and the angle-dependent optical filter/reflector may scatter a first portion of the light reflected by the angle-dependent optical filter/reflector back toward the angle-dependent optical filter/reflector. The scattered light that is incident on the angle-dependent optical filter/reflector with incident angles less than the first threshold value may be transmitted by the angle-dependent optical filter/reflector, thereby increasing the light extraction efficiency of the LED device. In some embodiments, the reflective surface may include a rough reflective surface for reflectively scatter incident light.

Optionally, in step 1710, a second portion of the light reflected by the angle-dependent optical filter/reflector may enter the LED, and may be reflected by a back reflector and/or a sidewall reflector of the LED back to the angle-dependent optical filter/reflector, or may be absorbed in the LED.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A light emission structure comprising:
a light emitting diode (LED) configured to emit light in a first wavelength range; and
an angle-dependent optical filter optically coupled to the LED and comprising:
a top layer;
a bottom layer, and
a stack of optical film layers between the top layer and the bottom layer and comprising:
first optical film layers including a first material having a first refractive index; and
second optical film layers including a second material having a second refractive index, the second optical film layers interleaved with the first optical film layers,
wherein a shortest optical path length in each optical film layer of the first optical film layers and the second optical film layers is ¼ of a second wavelength that is outside of the first wavelength range, and
wherein a shortest optical path length in each of the bottom layer and the top layer is different from ¼ of the second wavelength.

2. The light emission structure of claim 1, wherein:
the angle-dependent optical filter is characterized by a transmission wavelength range that varies with an angle of incidence (AOI) of light incident on the angle-dependent optical filter;
for a first AOI range, the transmission wavelength range at least partially overlaps with the first wavelength range of the light emitted from the LED, such that the angle-dependent optical filter is configured to mostly transmit light emitted from the LED and with AOIs in the first AOI range; and
for a second AOI range, the transmission wavelength range does not include or only includes a fraction of the first wavelength range of the light emitted from the LED, such that the angle-dependent optical filter is configured to mostly reflect light from the LED and with AOIs within the second AOI range.

3. The light emission structure of claim 2, wherein:
the first AOI range includes AOIs equal to or less than 18.5°; and
the second AOI range includes AOIs greater than 40°.

4. The light emission structure of claim 1, wherein the second wavelength is longer than wavelengths in the first wavelength range.

5. The light emission structure of claim 1, wherein the shortest optical path length of each of the bottom layer and the top layer is shorter than a quarter of the second wavelength.

6. The light emission structure of claim 5, wherein the shortest optical path length of each of the bottom layer and the top layer is ⅛ of the second wavelength.

7. The light emission structure of claim 1, wherein the shortest optical path length of each of the bottom layer and the top layer is longer than a quarter of the second wavelength.

8. The light emission structure of claim 7, wherein the shortest optical path length of each of the bottom layer and the top layer is 1.35 times of the quarter of the second wavelength.

9. The light emission structure of claim 1, further comprising a reflective surface between the LED and the angle-dependent optical filter, wherein the reflective surface is configured to scatter a first portion of light reflected by the angle-dependent optical filter back toward the angle-dependent optical filter.

10. The light emission structure of claim 9, wherein the reflective surface comprises an opening configured to:
allow at least a portion of the light emitted by the LED to pass through; and
allow a second portion of the light reflected by the angle-dependent optical filter to the opening to pass through and enter the LED.

11. The light emission structure of claim 1, wherein:
the first material includes gallium nitride (GaN) with a porosity less than 10%; and
the second material includes porous GaN with a porosity equal to or greater than 10%.

12. The light emission structure of claim 11, further comprising a transparent electrode for the LED, wherein the angle-dependent optical filter is between the LED and the transparent electrode.

13. The light emission structure of claim 1, wherein:
each of the first material and the second material includes a respective transparent dielectric material; and
the respective transparent dielectric material includes SiO₂, TiO₂, Ta₂O₅, Al₂O₃, HfO₂, or another metal oxide that is transparent to visible light.

14. The light emission structure of claim 1, wherein each of the bottom layer and the top layer includes the first material, the second material, or a third material different from the first material and the second material and having a third refractive index.

15. The light emission structure of claim 1, wherein the angle-dependent optical filter includes a notch filter, and wherein, for incident light with an AOI of 0°, a central wavelength of the notch filter is equal to the second wavelength.

16. A light emitting diode (LED) device comprising:
an array of LEDs configured to emit light in a first wavelength range; and
an angle-dependent optical reflector optically coupled to the array of LEDs, the angle-dependent optical reflector characterized by a reflection wavelength range that varies with an angle of incidence (AOI) of light incident on the angle-dependent optical reflector, wherein:
for incident light with AOIs within a first AOI range, the reflection wavelength range of the angle-dependent optical reflector does not include or only include a fraction of the first wavelength range such that a majority of the light that is emitted by the array of LEDs and is incident on the angle-dependent optical reflector at AOIs within the first AOI range is transmitted by the angle-dependent optical reflector; and
for incident light with AOIs in a second AOI range outside of the first AOI range, the reflection wavelength range of the angle-dependent optical reflector at least partially overlaps with the first wavelength range such that a majority of the light that is emitted by the array of LEDs and is incident on the angle-dependent optical reflector at AOIs in the second AOI range is reflected by the angle-dependent optical reflector back toward the array of LEDs.

17. The LED device of claim 16, wherein the angle-dependent optical reflector comprises:
a top layer;
a bottom layer; and
a layer stack between the top layer and the bottom layer, the layer stack including first optical film layers interleaved with second optical film layers,
wherein a shortest optical path length in each optical film layer of the first optical film layers and the second optical film layers is a quarter of a second wavelength that is outside of the first wavelength range; and
wherein a shortest optical path length in each of the bottom layer and the top layer is different from the quarter of the second wavelength.

18. The LED device of claim 17, wherein:
the first optical film layers include gallium nitride (GaN) with a porosity less than 10%; and
the second optical film layers include porous GaN with a porosity equal to or greater than 10%.

19. The LED device of claim 16, further comprising a reflective surface between the array of LEDs and the angle-dependent optical reflector, wherein the reflective surface is configured to scatter a first portion of the light that is reflected by the angle-dependent optical reflector back toward the angle-dependent optical reflector.

20. A method of collimating light emitted by a light emitting diode (LED), the method comprising:
receiving, by an angle-dependent optical reflector, light emitted by the LED and within a first wavelength range, wherein the angle-dependent optical reflector is characterized by a reflection wavelength range that varies with an angle of incidence (AOI) of light incident on the angle-dependent optical reflector;
transmitting, by the angle-dependent optical reflector, a majority of light received from the LED and with AOIs less than a first threshold value, wherein, for light with AOIs less than the first threshold value, the reflection wavelength range of the angle-dependent optical reflector does not include or only include a fraction of the first wavelength range; and
reflecting, by the angle-dependent optical reflector, a majority of light received from the LED and with AOIs greater than a second threshold value, wherein, for light with AOIs greater than the second threshold value, the reflection wavelength range of the angle-dependent optical reflector includes at a least of a portion of the first wavelength range.
